(19) United States
(12) Patent Application Publication
(10) Pub. No.: US 2023/0005865 A1
(43) Pub. Date: Jan. 5, 2023

(54) THREE-DIMENSIONAL MEMORY DEVICES, SYSTEMS, AND METHODS FOR FORMING THE SAME

(71) Applicant: YANGTZE MEMORY TECHNOLOGIES CO., LTD., Wuhan (CN)

(72) Inventors: Wei Liu, Wuhan (CN); Liang Chen, Wuhan (CN); Yanhong Wang, Wuhan (CN); Zhiliang Xia, Wuhan (CN); Yuancheng Yang, Wuhan (CN)

(21) Appl. No.: 17/587,656

(22) Filed: Jan. 28, 2022

Related U.S. Application Data
(63) Continuation of application No. PCT/CN2022/071723, filed on Jan. 13, 2022.

(30) Foreign Application Priority Data
Jun. 30, 2021 (CN) PCT/CN2021/103762

(51) Int. Cl. H01L 23/00; H01L 25/065; H01L 25/18; H01L 25/00

(52) U.S. Cl. CPC H01L 24/08; H01L 25/0657; H01L 25/18; H01L 24/80; H01L 25/50; H01L 2224/08145; H01L 2224/80895; H01L 2224/80896; H01L 2924/1431; H01L 2924/14511

(57) ABSTRACT

A three-dimensional 3D memory device includes a first semiconductor structure and a second semiconductor structure. The first semiconductor structure includes a first semiconductor layer and an array of NAND memory strings. The second semiconductor structure is under a second side of the first semiconductor layer. The second side of the first semiconductor layer is opposite to the first side of the first semiconductor layer. The second semiconductor structure includes a second semiconductor layer, a first peripheral circuit, and a second peripheral circuit. The first peripheral circuit includes a first transistor in contact with a first side of the second semiconductor layer. The second peripheral circuit includes a second transistor in contact with a second side of the second semiconductor layer. The second side of the second semiconductor layer is opposite to the first side of the second semiconductor layer.

### CROSS-REFERENCES TO RELATED APPLICATIONS

This application is continuation of International Application No. PCT/CN2022/071723, filed on Jan. 13, 2022, entitled “THREE-DIMENSIONAL MEMORY DEVICES, SYSTEMS, AND METHODS FOR FORMING THE SAME,” which claims the benefit of priority to International Application No. PCT/CN2021/103762, filed on Jun. 30, 2021, all of which are incorporated herein by reference in their entireties.

### BACKGROUND

The present disclosure relates to memory devices and fabrication methods thereof, and specifically, relates to the three-dimensional (3D) memory devices and fabrication methods thereof.

Planar memory cells are scaled to smaller sizes by improving process technology, circuit design, programming algorithm, and fabrication process. However, as feature sizes of the memory cells approach a lower limit, planar process and fabrication techniques become challenging and costly. As a result, memory density for planar memory cells approaches an upper limit.

A 3D memory architecture can address the density limitation in planar memory cells. The 3D memory architecture includes a memory array and peripheral circuits for facilitating operations of the memory array.

### SUMMARY

Implementations of 3D memory devices and methods for forming the same are disclosed herein.

In one aspect, a 3D memory device includes a first semiconductor structure and a second semiconductor structure. The first semiconductor structure includes a first semiconductor layer and an array of NAND memory strings. Sources of the array of NAND memory strings are in contact with a first side of the first semiconductor layer. The second semiconductor structure is under a second side of the first semiconductor layer. The second side of the first semiconductor layer is opposite to the first side of the first semiconductor layer. The second semiconductor structure includes a second semiconductor layer, a first peripheral circuit of the array of NAND memory strings, and a second peripheral circuit of the array of NAND memory strings. The first peripheral circuit includes a first transistor in contact with a first side of the second semiconductor layer. The second peripheral circuit includes a second transistor in contact with a second side of the second semiconductor layer. The second side of the second semiconductor layer is opposite to the first side of the second semiconductor layer.

In some implementations, the first semiconductor layer is between the array of NAND memory strings and the first peripheral circuit of the array of NAND memory strings. In some implementations, the first semiconductor layer includes a polysilicon layer.

In some implementations, the second semiconductor layer includes a silicon substrate. In some implementations, the second semiconductor structure further includes a first interconnect layer and a second interconnect layer such that the first peripheral circuit is between the first interconnect layer and the first side of the second semiconductor layer, and the second peripheral circuit is between the second interconnect layer and the second side of the second semiconductor layer.

In some implementations, the second semiconductor structure further includes a first through substrate via electrically connected between the first interconnect layer and the second interconnect layer. In some implementations, the first semiconductor structure further includes a first contact structure electrically connected between the first interconnect layer and a plurality of word lines of the array of NAND memory strings. In some implementations, the first contact structure penetrates the first semiconductor layer.

In some implementations, the second semiconductor structure further includes a pad-out structure, the second peripheral circuit of the array of NAND memory strings is between the pad-out structure and the second side of the second semiconductor structure.

In some implementations, the first semiconductor structure further includes a pad-out structure, the array of NAND memory strings is between the pad-out structure and the first side of the first semiconductor layer.

In some implementations, the first transistor includes a first gate dielectric, the second transistor includes a second gate dielectric, and a thickness of the first gate dielectric is greater than a thickness of the second gate dielectric. In some implementations, a difference between the thicknesses of the first and second gate dielectrics is at least 5-fold.

In another aspect, a system includes a memory device configured to store data. The memory device includes a first semiconductor structure and a second semiconductor structure. The first semiconductor structure includes a first semiconductor layer and an array of NAND memory strings. Sources of the array of NAND memory strings are in contact with a first side of the first semiconductor layer. The second semiconductor structure is under a second side of the first semiconductor layer. The second side of the first semiconductor layer is opposite to the first side of the first semiconductor layer. The second semiconductor structure includes a second semiconductor layer, a first peripheral circuit of the array of NAND memory strings, and a second peripheral circuit of the array of NAND memory strings. The first peripheral circuit includes a first transistor in contact with a first side of the second semiconductor layer. The second peripheral circuit includes a second transistor in contact with a second side of the second semiconductor layer. The second side of the second semiconductor layer is opposite to the first side of the second semiconductor layer. The system also includes a memory controller coupled to the memory device and configured to control the array of memory cells through the first peripheral circuit and the second peripheral circuit.

In still another aspect, a method for forming a 3D memory device is disclosed. A first transistor is formed on a first side of a substrate. A semiconductor layer is formed over the first transistor on the first side of the substrate. An array of NAND memory strings is formed over the semiconductor layer. A second transistor is formed on a second side of the substrate opposite to the first side.

In some implementations, a first interconnect layer is formed on the first transistor. In some implementations, a polysilicon layer is formed over the first interconnect layer.

In some implementations, the substrate is thinned before forming the second transistor.

In some implementations, a pad-out structure is formed above the array of NAND memory strings on the first side of the substrate. In some implementations, a first contact structure is formed before forming the pad-out structure, and the first contact structure is electrically connected between the first interconnect layer and the pad-out structure.

In some implementations, a pad-out structure is formed above the second transistor on the second side of the substrate. In some implementations, a through substrate via is formed extending through the substrate. In some implementations, the through substrate via electrically connects the first interconnect layer and the second interconnect layer.

### BRIEF DESCRIPTION OF THE DRAWINGS

The accompanying drawings, which are incorporated herein and form a part of the specification, illustrate aspects of the present disclosure and, together with the description, further serve to explain the principles of the present disclosure and to enable a person skilled in the pertinent art to make and use the present disclosure.

FIG. 1 illustrates a schematic view of a cross-section of a 3D memory device, according to some aspects of the present disclosure.

FIG. 2 illustrates a schematic circuit diagram of a memory device including peripheral circuits, according to some aspects of the present disclosure.

FIG. 3 illustrates a block diagram of a memory device including a memory cell array and peripheral circuits, according to some aspects of the present disclosure.

FIG. 4A illustrates a block diagram of peripheral circuits provided with various voltages, according to some aspects of the present disclosure.

FIG. 4B illustrates a schematic diagram of peripheral circuits provided with various voltages arranged in separate semiconductor structures, according to some aspects of the present disclosure.

FIGS. 5A and 5B illustrate a perspective view and a side view, respectively, of a planar transistor, according to some aspects of the present disclosure.

FIGS. 6A and 6B illustrate a perspective view and a side view, respectively, of a 3D transistor, according to some aspects of the present disclosure.

FIG. 7 illustrates a circuit diagram of a word line driver and a page buffer, according to some aspects of the present disclosure.

FIG. 8 illustrates a side view of a NAND memory string in a 3D memory device, according to some aspects of the present disclosure.

FIGS. 9A and 9B illustrate schematic views of cross-sections of 3D memory devices having different pad-out structures, according to various aspects of the present disclosure.

FIGS. 10A and 10B illustrate side views of various examples of the 3D memory devices in FIGS. 9A and 9B, according to various aspects of the present disclosure.

FIGS. 11-16 illustrate a fabrication process for forming the 3D memory devices in FIG. 10A, according to some aspects of the present disclosure.

FIG. 17 illustrates a flowchart of a method for forming the 3D memory devices in FIGS. 11-16, according to some aspects of the present disclosure.

FIGS. 18-23 illustrate a fabrication process for forming the 3D memory devices in FIG. 10B, according to some aspects of the present disclosure.

FIG. 24 illustrates a block diagram of an exemplary system having a memory device, according to some aspects of the present disclosure.

FIG. 25A illustrates a diagram of an exemplary memory card having a memory device, according to some aspects of the present disclosure.

FIG. 25B illustrates a diagram of an exemplary solid-state drive (SSD) having a memory device, according to some aspects of the present disclosure.

The present disclosure will be described with reference to the accompanying drawings.

### DETAILED DESCRIPTION

Although specific configurations and arrangements are discussed, it should be understood that this is done for illustrative purposes only. As such, other configurations and arrangements can be used without departing from the scope of the present disclosure. Also, the present disclosure can also be employed in a variety of other applications. Functional and structural features as described in the present disclosures can be combined, adjusted, and modified with one another and in ways not specifically depicted in the drawings, such that these combinations, adjustments, and modifications are within the scope of the present disclosure.

In general, terminology may be understood at least in part from usage in context. For example, the term “one or more” as used herein, depending at least in part upon context, may be used to describe any feature, structure, or characteristic in a singular sense or may be used to describe combinations of features, structures, or characteristics in a plural sense. Similarly, terms, such as “a,” “an,” or “the,” again, may be understood to convey a singular usage or to convey a plural usage, depending at least in part upon context. In addition, the term “based on” may be understood as not necessarily intended to convey an exclusive set of factors and may, instead, allow for existence of additional factors not necessarily expressly described, again, depending at least in part on context.

It should be readily understood that the meaning of “on,” “above,” and “over” in the present disclosure should be interpreted in the broadest manner such that “on” not only means “directly on” something but also includes the meaning of “on” something with an intermediate feature or a layer therebetween, and that “above” or “over” not only means the meaning of “above” or “over” something but can also include the meaning it is “above” or “over” something with no intermediate feature or layer therebetween (i.e., directly on something).

Further, spatially relative terms, such as “beneath,” “below,” “lower,” “above,” “upper,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations), and the spatially relative descriptors used herein may likewise be interpreted accordingly.

As used herein, the term “layer” refers to a material portion including a region with a thickness. A layer can extend over the entirety of an underlying or overlying structure or may have an extent less than the extent of an underlying or overlying structure. Further, a layer can be a region of a homogeneous or inhomogeneous continuous structure that has a thickness less than the thickness of the continuous structure. For example, a layer can be located between any pair of horizontal planes between, or at, a top surface and a bottom surface of the continuous structure. A layer can extend horizontally, vertically, and/or along a tapered surface. A substrate can be a layer, can include one or more layers therein, and/or can have one or more layers thereupon, thereabove, and/or therebelow. A layer can include multiple layers. For example, an interconnect layer can include one or more conductors and contact layers (in which interconnect lines and/or vertical interconnect access (via) contacts are formed) and one or more dielectric layers.

With the development of 3D memory devices, such as 3D NAND Flash memory devices, the more stacked layers (e.g., more word lines and the resulting more memory cells) require more peripheral circuits (and the components, e.g., transistors, forming the peripheral circuits) for operating the 3D memory devices. For example, the number and/or size of page buffers needs to increase to match the increased number of memory cells. In another example, the number of string drivers in the word line driver is proportional to the number of word lines in the 3D NAND Flash memory. Thus, the continuous increase of the word lines also increases the area occupied by the word line driver, as well as the complexity of metal routings, sometimes even the number of metal layers. Moreover, in some 3D memory devices in which the memory cell array and peripheral circuits are fabricated on different substrates and bonded together, the continuous increase of peripheral circuits' areas makes it the bottleneck for reducing the total chip size since the memory cell array can be scaled up vertically by increasing the number of levels instead of increasing the planar size.

Thus, it is desirable to reduce the planar areas occupied by the peripheral circuits of the 3D memory devices with the increased numbers of peripheral circuits and the transistors thereof. However, scaling down the transistor size of the peripheral circuits following the advanced complementary metal-oxide-semiconductor (CMOS) technology node trend used for the logic devices would cause a significant cost increase and higher leakage current, which are undesirable for memory devices. Moreover, because the 3D NAND Flash memory devices require a relatively high voltage (e.g., above 5 V) in certain memory operations, such as program and erase, unlike logic devices, which can reduce its working voltage as the CMOS technology node advances, the voltage provided to the memory peripheral circuits cannot be reduced. As a result, scaling down the memory peripheral circuit sizes by following the trend for advancing the CMOS technology nodes, like the normal logic devices, becomes infeasible.

To address one or more of the aforementioned issues, the present disclosure introduces various solutions in which the peripheral circuits of a memory device are disposed in different planes (levels, tiers) in the vertical direction, i.e., formed over one another, to reduce the planar chip size of the peripheral circuits, as well as the total chip size of the memory device. In some implementations, the memory cell array (e.g., NAND memory strings), the memory peripheral circuits provided with a relatively high voltage (e.g., above 5 V), and the memory peripheral circuits provided with a relatively low voltage (e.g., below 1.3 V) are disposed in different planes in the vertical direction, i.e., formed over one another, to further reduce the chip size. In addition, in some implementations, the memory peripheral circuits provided with a relatively high voltage (e.g., above 5 V), and the memory peripheral circuits provided with a relatively low voltage (e.g., below 1.3 V) are disposed on opposite sides of the same substrate to further reduce the chip size. The 3D memory device architectures and fabrication processes disclosed in the present disclosure can be easily scaled up vertically to stack more peripheral circuits in different planes to further reduce the chip size.

The peripheral circuits can be separated into different planes in the vertical direction based on different performance requirements, for example, the voltages applied to the transistors thereof, which affect the dimensions of the transistors (e.g., gate dielectric thickness), dimensions of the substrates in which the transistors are formed (e.g., substrate thickness), and thermal budgets (e.g., the interconnect material). Thus, peripheral circuits with different dimension requirements (e.g., gate dielectric thickness and substrate thickness) and thermal budgets can be fabricated in different processes to reduce the design and process constraints from each other, thereby improving the device performance and fabrication complexity.

According to some aspects of the present disclosure, a first layer of memory peripheral circuits may be formed on a first side of a substrate, and the memory cell array may be formed on the memory peripheral circuits on the same side of the substrate. Then the substrate may be flipped over and thinned, and a second layer of memory peripheral circuits may be formed on a second side of the substrate opposite to the first side. As a result, the fabrication size of the memory peripheral circuits may be doubled on one substrate to reduce the chip size and the manufacturing cost. Further, the second layer of memory peripheral circuits may be the low-voltage memory peripheral circuits provided with a relatively low voltage (e.g., below 1.3 V), and may be formed after the fabrication of the memory cell array. Hence, the low-voltage memory peripheral circuits will not be affected by the high temperature during the manufacturing of the memory cell array. In addition, the channel length of the low-voltage memory peripheral circuits can be reduced, and the input/output (I/O) speed of the memory devices can be improved as well. In some implementations, the minimality of the channel length of the low-voltage memory peripheral circuits can be further achieved.

The 3D memory device architectures and fabrication processes disclosed in the present disclosure also have the flexibility to allow various device pad-out schemes to meet different needs and different designs of the memory cell array. In some implementations, the pad-out interconnect layer is formed from the side of the semiconductor structure that has the peripheral circuits to shorten the interconnect distance between the pad-out interconnect layer and the transistors of the peripheral circuits to reduce the parasitic capacitance from the interconnects and improve the electric performance. In some implementations, the pad-out interconnect layer is formed on the side of the semiconductor structure that has the memory cell array to enable interlayer vias (LLVs, e.g., submicron-level) for pad-out interconnects with high I/O throughput and low fabrication complicity.

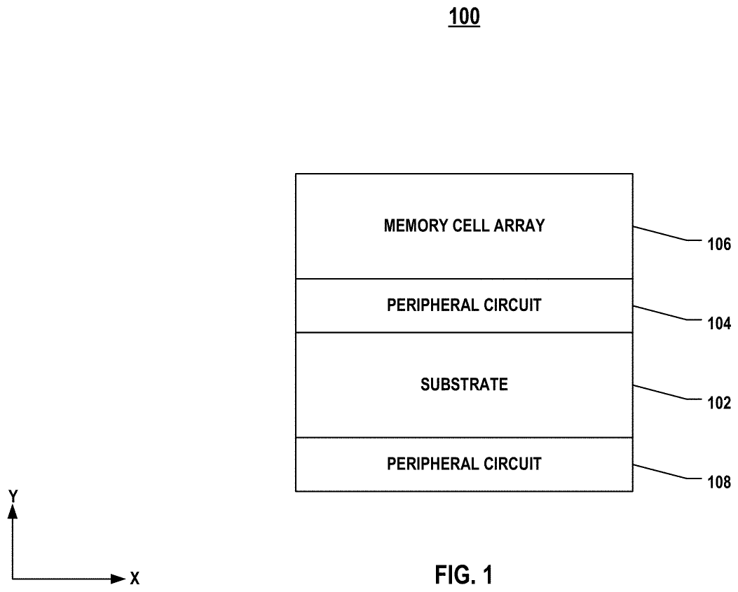

FIG. 1 illustrates a schematic view of a cross-section of a 3D memory device 100, according to some aspects of the present disclosure. 3D memory device 100 represents an example of a periphery under cell (PUC) structure. In some implementations, a peripheral circuit 104 may be first formed on a substrate 102, and a memory cell array 106 may then be formed on peripheral circuit 104. In some implementations, peripheral circuit 104 may be formed over substrate 102, and a semiconductor layer, e.g., a polysilicon layer, may be formed over peripheral circuit 104. Memory cell array 106 may be formed over the semiconductor layer. In some implementations, the PUC wafer is filliped over, and a thinning operation may be performed on substrate 102. A peripheral circuit 108 may be then formed on thinned substrate 102.

It is noted that x- and y-axes are added in FIG. 1 to further illustrate the spatial relationships of the components of a semiconductor device. Substrate 102 of 3D memory device 100 includes two lateral surfaces (e.g., a top surface and a bottom surface) extending laterally in the x-direction (the lateral direction or width direction). As used herein, whether one component (e.g., a layer or a device) is “on,” “above,” or “below” another component (e.g., a layer or a device) of a semiconductor device is determined relative to substrate 102 of 3D memory device 100 in the y-direction (the vertical direction or thickness direction). The same notion for describing the spatial relationships is applied throughout the present disclosure.

In some implementations, memory cell array 106 includes an array of NAND Flash memory cells. For ease of description, a NAND Flash memory cell array may be used as an example for describing memory cell array 106 in the present disclosure. But it is understood that memory cell array 106 is not limited to NAND Flash memory cell array and may include any other suitable types of memory cell arrays, such as NOR Flash memory cell array, phase change memory (PCM) cell array, resistive memory cell array, magnetic memory cell array, spin transfer torque (STT) memory cell array, to name a few.

Memory cell array 106 may be a NAND Flash memory device in which memory cells are provided in the form of an array of 3D NAND memory strings and/or an array of two-dimensional (2D) NAND memory cells. NAND memory cells can be organized into pages or fingers, which are then organized into blocks in which each NAND memory cell is coupled to a separate line called a bit line (BL). All cells with the same vertical position in the NAND memory cell can be coupled through the control gates by a word line (WL). In some implementations, a memory plane contains a certain number of blocks that are coupled through the same bit line. Memory cell array 106 may include one or more memory planes, and the peripheral circuits that are needed to perform all the read/program (write)/erase operations can be included in peripheral circuit 104 and peripheral circuit 108.

In some implementations, the array of NAND memory cells is an array of 2D NAND memory cells, each of which includes a floating-gate transistor. The array of 2D NAND memory cells includes a plurality of 2D NAND memory strings, each of which includes a plurality of memory cells connected in series (resembling a NAND gate) and two select transistors, according to some implementations. Each 2D NAND memory string is arranged in the same plane (i.e., referring to herein a flat, two-dimensional (2D) surface, different from the term “memory plane” in the present discourse) on the substrate, according to some implementations. In some implementations, the array of NAND memory cells is an array of 3D NAND memory strings, each of which extends vertically above the substrate (in 3D) through a stack structure, e.g., a memory stack. Depending on the 3D NAND technology (e.g., the number of layers/tiers in the memory stack), a 3D NAND memory string typically includes a certain number of NAND memory cells, each of which includes a floating-gate transistor or a charge-trap transistor.

As shown in FIG. 1, 3D memory device 100 may also include peripheral circuit 104 and peripheral circuit 108, each including some of the peripheral circuits of memory cell array 106. That is, the peripheral circuits of memory cell array 106 may be separated into at least two other semiconductor structures (e.g., peripheral circuit 104 and peripheral circuit 108 in FIG. 1). The peripheral circuits (a.k.a. control and sensing circuits) can include any suitable digital, analog, and/or mixed-signal circuits used for facilitating the operations of memory cell array 106. For example, the peripheral circuits can include one or more of a page buffer, a decoder (e.g., a row decoder and a column decoder), a sense amplifier, a driver (e.g., a word line driver), an I/O circuit, a charge pump, a voltage source or generator, a current or voltage reference, any portions (e.g., a sub-circuit) of the functional circuits mentioned above, or any active or passive components of the circuit (e.g., transistors, diodes, resistors, or capacitors). The peripheral circuits in peripheral circuit 104 and peripheral circuit 108 may use CMOS technology, e.g., which can be implemented with logic processes in any suitable technology nodes.

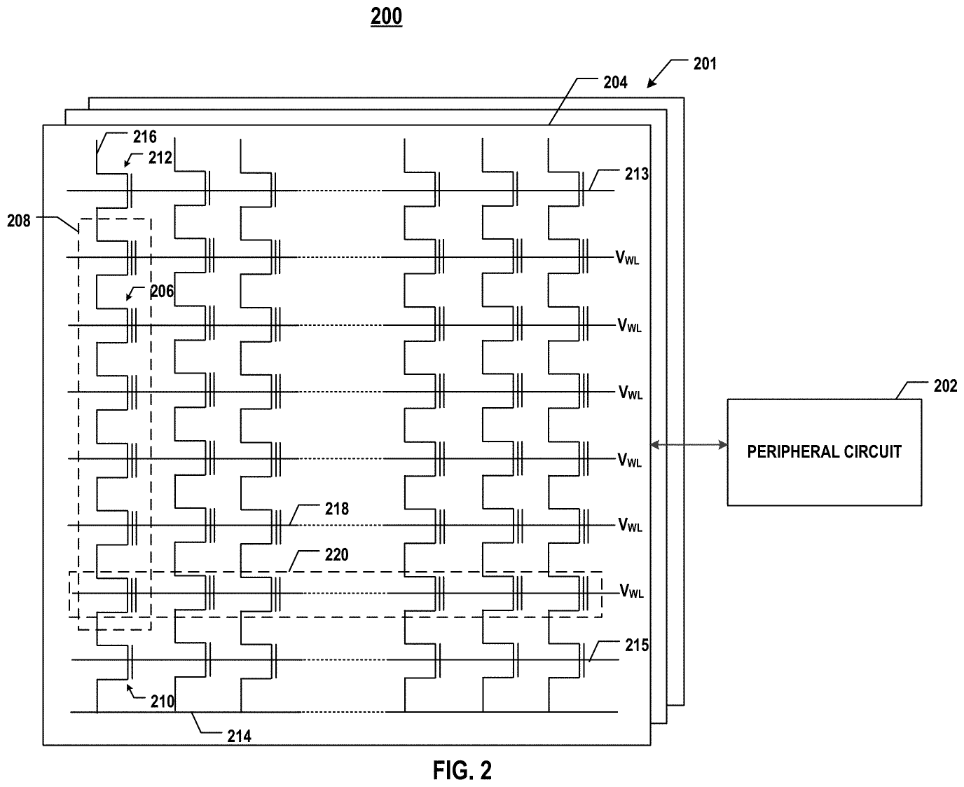

FIG. 2 illustrates a schematic circuit diagram of a memory device 200 including peripheral circuits, according to some aspects of the present disclosure. Memory device 200 can include a memory cell array 201 and peripheral circuits 202 coupled to memory cell array 201. 3D memory device 100 may be examples of memory device 200 in which memory cell array 201 and at least two portions of peripheral circuits 202 may be included in various peripheral circuit 104 and peripheral circuit 108.

Memory cell array 201 can be a NAND Flash memory cell array in which memory cells 206 are provided in the form of an array of NAND memory strings 208 each extending vertically above a substrate (not shown). In some implementations, each NAND memory string 208 includes a plurality of memory cells 206 coupled in series and stacked vertically. Each memory cell 206 can hold a continuous, analog value, such as an electrical voltage or charge, that depends on the number of electrons trapped within a region of memory cell 206. Each memory cell 206 can be either a floating gate type of memory cell including a floating-gate transistor or a charge trap type of memory cell including a charge-trap transistor.

In some implementations, each memory cell 206 is a single-level cell (SLC) that has two possible memory states and thus, can store one bit of data. For example, the first memory state “0” can correspond to a first range of voltages, and the second memory state “1” can correspond to a second range of voltages. In some implementations, each memory cell 206 is a multi-level cell (MLC) that is capable of storing more than a single bit of data in more than four memory states. For example, the MLC can store two bits per cell, three bits per cell (also known as triple-level cell (TLC)), or four bits per cell (also known as a quad-level cell (QLC)). Each MLC can be programmed to assume a range of possible nominal storage values. In one example, if each MLC stores two bits of data, then the MLC can be programmed to assume one of three possible programming levels from an erased state by writing one of three possible nominal storage values to the cell. A fourth nominal storage value can be used for the erased state.

As shown in FIG. 2, each NAND memory string 208 can include a source select gate (SSG) transistor 210 at its source end and a drain select gate (DSG) transistor 212 at its drain end. SSG transistor 210 and DSG transistor 212 can be configured to activate selected NAND memory strings 208 (columns of the array) during read and program operations. In some implementations, SSG transistors 210 of NAND memory strings 208 in the same block 204 are coupled through a same source line (SL) 214, e.g., a common SL, for example, to the ground. DSG transistor 212 of each NAND memory string 208 is coupled to a respective bit line 216 from which data can be read or programmed via an output bus (not shown), according to some implementations. In some implementations, each NAND memory string 208 is configured to be selected or deselected by applying a select voltage (e.g., above the threshold voltage of DSG transistor 212) or a deselect voltage (e.g., 0 V) to respective DSG transistor 212 through one or more DSG lines 213 and/or by applying a select voltage (e.g., above the threshold voltage of SSG transistor 210) or a deselect voltage (e.g., 0 V) to respective SSG transistor 210 through one or more SSG lines 215.

As shown in FIG. 2, NAND memory strings 208 can be organized into multiple blocks 204, each of which can have a common source line 214. In some implementations, each block 204 is the basic data unit for erase operations, i.e., all memory cells 206 on the same block 204 are erased at the same time. Memory cells 206 of adjacent NAND memory strings 208 can be coupled through word lines 218 that select which row of memory cells 206 is affected by read and program operations. In some implementations, each word line 218 is coupled to a page 220 of memory cells 206, which is the basic data unit for program and read operations. The size of one page 220 in bits can correspond to the number of NAND memory strings 208 coupled by word line 218 in one block 204. Each word line 218 can include a plurality of control gates (gate electrodes) at each memory cell 206 in respective page 220 and a gate line coupling the control gates.

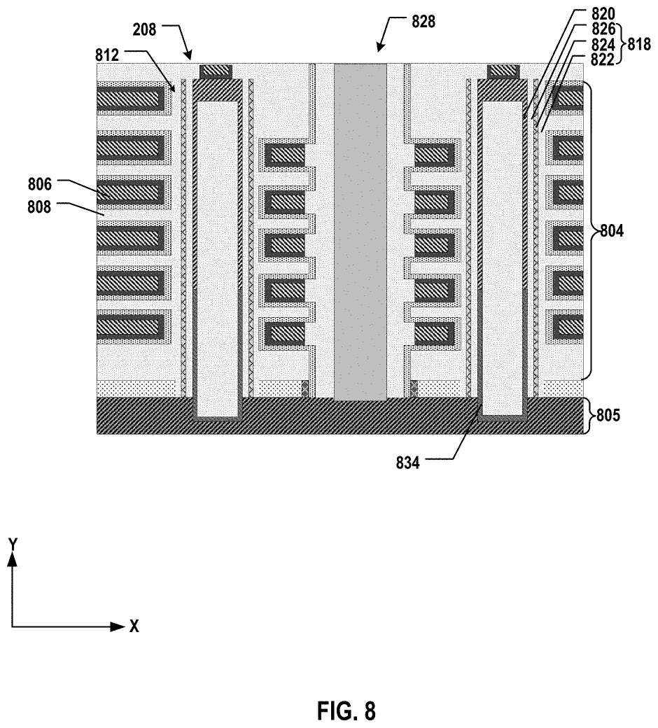

FIG. 8 illustrates a side view of NAND memory string 208 in 3D memory devices, according to some aspects of the present disclosure. As shown in FIG. 8, NAND memory string 208 can extend vertically through a memory stack 804 above a semiconductor layer 805. Memory stack 804 may include interleaved gate conductive layers 806 and dielectric layers 808. The number of the pairs of gate conductive layers 806 and dielectric layers 808 in memory stack 804 can determine the number of memory cells 206 in memory cell array 201. Gate conductive layer 806 may include conductive materials including, but not limited to, tungsten (W), cobalt (Co), copper (Cu), aluminum (Al), polysilicon, doped silicon, silicides, or any combination thereof. In some implementations, each gate conductive layer 806 includes a metal layer, such as a tungsten layer. In some implementations, each gate conductive layer 806 includes a doped polysilicon layer. Each gate conductive layer 806 can include control gates surrounding the memory cells, the gates of DSG transistors 212, or the gates of SSG transistors 210, and can extend laterally as DSG line 213 at the top of memory stack 804, SSG line 215 at the bottom of memory stack 804, or word line 218 between DSG line 213 and SSG line 215.

As shown in FIG. 8, NAND memory string 208 includes a channel structure 812 extending vertically through memory stack 804. In some implementations, channel structure 812 includes a channel hole filled with semiconductor material(s) (e.g., as a semiconductor channel 820) and dielectric material(s) (e.g., as a memory film 818). In some implementations, semiconductor channel 820 includes silicon, such as polysilicon. In some implementations, memory film 818 is a composite dielectric layer including a tunneling layer 826, a storage layer 824 (also known as a “charge trap/storage layer”), and a blocking layer 822. Channel structure 812 may have a cylinder shape (e.g., a pillar shape). Semiconductor channel 820, tunneling layer 826, storage layer 824, blocking layer 822 are arranged radially from the center toward the outer surface of the pillar in this order, according to some implementations. Tunneling layer 826 may include silicon oxide, silicon oxynitride, or any combination thereof. Storage layer 824 may include silicon nitride, silicon oxynitride, silicon, or any combination thereof. Blocking layer 822 may include silicon oxide, silicon oxynitride, high dielectric constant (high-k) dielectrics, or any combination thereof. In one example, memory film 818 may include a composite layer of silicon oxide/silicon oxynitride/silicon oxide (ONO).

As shown in FIG. 8, in some implementations, semiconductor layer 805 is in contact with semiconductor channel 820 of a bottom open channel structure 812 on the source end of NAND memory string 208. Parts of memory film 818 of channel structure 812 on the source end may be removed to expose semiconductor channel 820 to contact semiconductor layer 805. In some implementations, part of semiconductor channel 820 on the source end of NAND memory string 208 is doped to form a doped region 834 that is in contact with semiconductor layer 805. Semiconductor layer 805 may include semiconductor materials, such as polysilicon. In some implementations, semiconductor layer 805 includes N-type doped polysilicon to enable GILD erase operations. A slit structure 828 may extend vertically through memory stack 804 and be in contact with semiconductor layer 805.

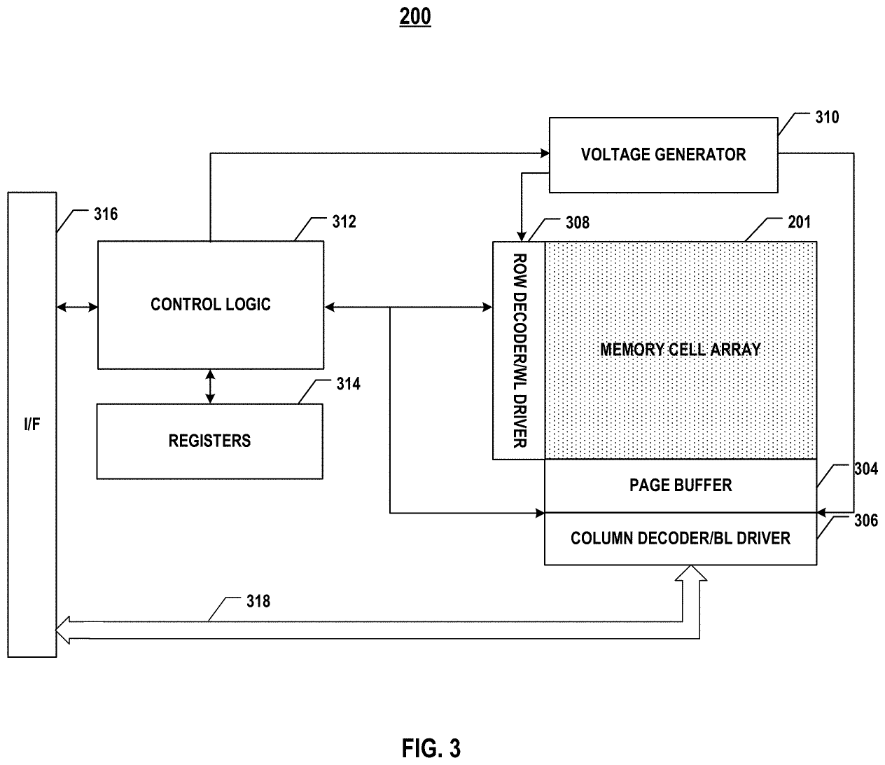

Referring to FIG. 2, peripheral circuits 202 can be coupled to memory cell array 201 through bit lines 216, word lines 218, source lines 214, SSG lines 215, and DSG lines 213. As described above, peripheral circuits 202 can include any suitable circuits for facilitating the operations of memory cell array 201 by applying and sensing voltage signals and/or current signals through bit lines 216 to and from each target memory cell 206 through word lines 218, source lines 214, SSG lines 215, and DSG lines 213. Peripheral circuits 202 can include various types of peripheral circuits formed using CMOS technologies. For example, FIG. 3 illustrates some exemplary peripheral circuits 202 including a page buffer 304, a column decoder/bit line driver 306, a row decoder/word line driver 308, a voltage generator 310, control logic 312, registers 314, an interface (I/F) 316, and a data bus 318. It is understood that in some examples, additional peripheral circuits 202 may be included as well.

Page buffer 304 can be configured to buffer data read from or programmed to memory cell array 201 according to the control signals of control logic 312. In one example, page buffer 304 may store one page of program data (write data) to be programmed into one page 220 of memory cell array 201. In another example, page buffer 304 also performs program verify operations to ensure that the data has been properly programmed into memory cells 206 coupled to selected word lines 218.

Row decoder/word line driver 308 can be configured to be controlled by control logic 312 and select block 204 of memory cell array 201 and a word line 218 of selected block 204. Row decoder/word line driver 308 can be further configured to drive memory cell array 201. For example, row decoder/word line driver 308 may drive memory cells 206 coupled to the selected word line 218 using a word line voltage generated from voltage generator 310.

Column decoder/bit line driver 306 can be configured to be controlled by control logic 312 and select one or more 3D NAND memory strings 208 by applying bit line voltages generated from voltage generator 310. For example, column decoder/bit line driver 306 may apply column signals for selecting a set of N bits of data from page buffer 304 to be outputted in a read operation.

Control logic 312 can be coupled to each peripheral circuit 202 and configured to control operations of peripheral circuits 202. Registers 314 can be coupled to control logic 312 and include status registers, command registers, and address registers for storing status information, command operation codes (OP codes), and command addresses for controlling the operations of each peripheral circuit 202.

Interface 316 can be coupled to control logic 312 and configured to interface memory cell array 201 with a memory controller (not shown). In some implementations, interface 316 acts as a control buffer to buffer and relay control commands received from the memory controller and/or a host (not shown) to control logic 312 and status information received from control logic 312 to the memory controller and/or the host. Interface 316 can also be coupled to page buffer 304 and column decoder/bit line driver 306 via data bus 318 and act as an I/O interface and a data buffer to buffer and relay the program data received from the memory controller and/or the host to page buffer 304 and the read data from page buffer 304 to the memory controller and/or the host. In some implementations, interface 316 and data bus 318 are parts of an I/O circuit of peripheral circuits 202.

Voltage generator 310 can be configured to be controlled by control logic 312 and generate the word line voltages (e.g., read voltage, program voltage, pass voltage, local voltage, and verification voltage) and the bit line voltages to be supplied to memory cell array 201. In some implementations, voltage generator 310 is part of a voltage source that provides voltages at various levels of different peripheral circuits 202 as described below in detail. Consistent with the scope of the present disclosure, in some implementations, the voltages provided by voltage generator 310, for example, to row decoder/word line driver 308, column decoder/bit line driver 306, and page buffer 304 are above certain levels that are sufficient to perform the memory operations. For example, the voltages provided to the page buffer circuits in page buffer 304 and/or the logic circuits in control logic 312 may be between 1.3 V and 5 V, such as 3.3 V, and the voltages provided to the driving circuits in row decoder/word line driver 308 and/or column decoder/bit line driver 306 may be between 5 V and 30 V.

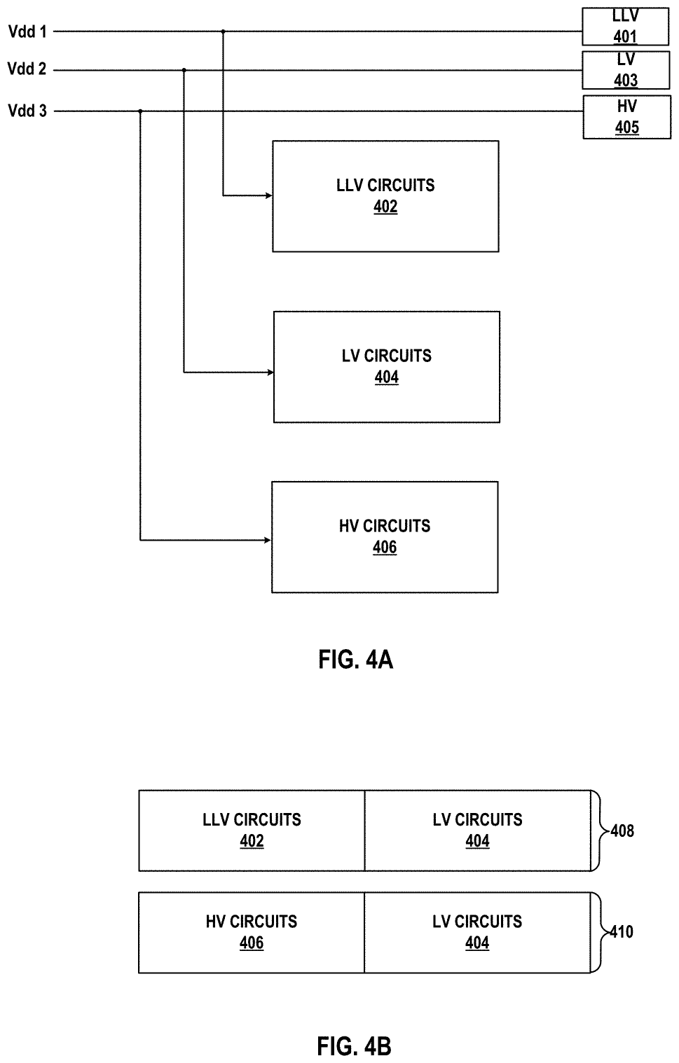

Different from logic devices (e.g., microprocessors), memory devices, such as 3D NAND Flash memory, require a wide range of voltages to be supplied to different memory peripheral circuits. For example, FIG. 4A illustrates a block diagram of peripheral circuits provided with various voltages, according to some aspects of the present disclosure. In some implementations, a memory device (e.g., memory device 200) includes a low low voltage (LLV) source 401, a low voltage (LV) source 403, and a high voltage (HV) source 405, each of which is configured to provide a voltage at a respective level (Vdd1, Vdd2, or Vdd3). For example, Vdd3>Vdd2>Vdd1. Each voltage source 401, 403, or 405 can receive a voltage input at a suitable level from an external power source (e.g., a battery). Each voltage source 401, 403, or 405 can also include voltage converters and/or voltage regulators to convert the external voltage input to the respective level (Vdd1, Vdd2, or Vdd3) and maintain and output the voltage at the respective level (Vdd1, Vdd2, or Vdd3) through a corresponding power rail. In some implementations, voltage generator 310 of memory device 200 is part of voltage sources 401, 403, and 405.

In some implementations, LLV source 401 is configured to provide a voltage below 1.3 V, such as between 0.9 V and 1.2 V (e.g., 0.9 V, 0.95 V, 1 V, 1.05 V, 1.1 V, 1.15 V, 1.2 V, any range bounded by the lower end by any of these values, or in any range defined by any two of these values). In one example, the voltage is 1.2 V. In some implementations, LV source 403 is configured to provide a voltage between 1.3 V and 3.3 V (e.g., 1.3 V, 0.1.4 V, 1.5 V, 1.6 V, 1.7 V, 1.8 V, 1.9 V, 2 V, 2.1 V, 2.2 V, 2.3 V, 2.4 V, 2.5 V, 2.6 V, 2.7 V, 2.8 V, 2.9 V, 3 V, 3.1 V, 3.2 V, 3.3 V, any range bounded by the lower end by any of these values, or in any range defined by any two of these values). In one example, the voltage is 3.3 V. In some implementations, HV source 405 is configured to provide a voltage greater than 3.3 V, such as between 5 V and 30 V (e.g., 5 V, 6 V, 7 V, 8 V, 9 V, 10 V, 11 V, 12 V, 13 V, 14 V, 15 V, 16 V, 17 V, 18 V, 19 V, 20 V, 21 V, 22 V, 23 V, 24 V, 25 V, 26 V, 27 V, 28 V, 29 V, 30 V, any range bounded by the lower end by any of these values, or in any range defined by any two of these values). It is understood that the voltage ranges described above with respect to HV source 405, LV source 403, and LLV source 401 are for illustrative purposes and non-limiting, and any other suitable voltage ranges may be provided by HV source 405, LV source 403, and LLV source 401.

Based on their suitable voltage levels (Vdd1, Vdd 2, or Vdd3), the memory peripheral circuits (e.g., peripheral circuits 202) can be categories into LLV circuits 402, LV circuits 404, and HV circuits 406, which can be coupled to LLV source 401, LV source 403, and HV source 405, respectively. In some implementations, HV circuits 406 includes one or more driving circuits that are coupled to the memory cell array (e.g., memory cell array 201) through word lines, bit lines, SSG lines, DSG lines, source lines, etc., and configured to drive the memory cell array by applying a voltage at a suitable level to the word lines, bit lines, SSG lines, DSG lines, source lines, etc., when performing memory operations (e.g., read, program, or erase). In one example, HV circuit 406 may include word line driving circuits (e.g., in row decoder/word line driver 308) that are coupled to word lines and apply a program voltage (Vprog) or a pass voltage (Vpass) in the range of, for example, 5 V and 30 V, to the word lines during program operations. In another example, HV circuit 406 may include bit line driving circuits (e.g., in column decoder/bit line driver 306) that are coupled to bit lines and apply an erase voltage (Veras) in the range of, for example, 5 V and 30 V, to bit lines during erase operations. In some implementations, LV circuits 404 include page buffer circuits (e.g., in latches of page buffer 304) and are configured to buffer the data read from or programmed to the memory cell array. For example, the page buffer may be provided with a voltage of, for example, 3.3 V, by LV source 403. LV circuits 404 can also include logic circuits (e.g., in control logic 312). In some implementations, LLV circuits 402 include an I/O circuit (e.g., in interface 316 and/or data bus 318) configured to interface the memory cell array with a memory controller. For example, the I/O circuit may be provided with a voltage of, for example, 1.2 V, by LLV source 401.

As described above, to reduce the total area occupied by the memory peripheral circuits, peripheral circuits 202 can be separately formed in different planes based on different performance requirements, such as the applied voltages. For example, FIG. 4B illustrates a schematic diagram of peripheral circuits provided with various voltages arranged in separate semiconductor structures, according to some aspects of the present disclosure. In some implementations, LLV circuits 402 and HV circuits 406 are separated, for example, in semiconductor structures 408 and 410, respectively, due to their significant difference in voltages and the resulting difference in device dimensions, such as different semiconductor layer (e.g., substrate or thinned substrate) thicknesses and different gate dielectric thicknesses. In one example, the thickness of the semiconductor layer (e.g., a substrate or a thinned substrate) in which HV circuits 406 are formed in semiconductor structure 410 may be larger than the thickness of the semiconductor layer (e.g., a substrate or a thinned substrate) in which LLV circuits 402 are formed in semiconductor structure 408. In another example, the thickness of the gate dielectric of transistors forming HV circuits 406 may be larger than the thickness of the gate dielectric of transistors forming LLV circuits 402. For example, the thickness difference may be at least 5-fold. It is understood that LLV circuits 402 and HV circuits 406 in different planes may be formed on opposite sides of a substrate or a semiconductor layer (e.g., in FIG. 1).

LV circuits 404 can be formed in either semiconductor structure 408 or 410, or in another semiconductor, i.e., in the same plane as LLV circuits 402 or HV circuits 406, or a different plane from LLV circuits 402 and HV circuits 406. As shown in FIG. 4B, in some implementations, some of LV circuits 404 are formed in semiconductor structure 408, i.e., in the same plane as LLV circuits 402, while some of LV circuits 404 are formed in semiconductor structure 410, i.e., in the same plane as HV circuits 406. That is, LV circuits 404 can be separated into different planes as well. The thickness of the gate dielectric of transistors forming LV circuits 404 in semiconductor structure 408 can be the same as the thickness of the gate dielectric of transistors forming LV circuits 404 in semiconductor structure 410, for example, when the same voltage is applied to LV circuits 404 in different semiconductor structures 408 and 410. In some implementations, the same voltage is applied to both LV circuits 404 in semiconductor structure 408 and the LV circuits 404 in semiconductor structure 410, such that the voltage applied to HV circuits 406 in semiconductor structure 410 is higher than the voltage applied to LV circuits 404 in semiconductor structure 408 or 410, which is in turn higher than the voltage applied to LLV circuits 402 in semiconductor structure 408. Moreover, since the voltage applied to LV circuits 404 is between the voltages applied to HV circuits 406 and LLV circuits 402, the thickness of the gate dielectric of transistors forming LV circuits 404 is between the thickness of the gate dielectric of transistors forming HV circuits 406 and the thickness of the gate dielectric of transistors forming LLV circuits 402, according to some implementations. For example, the gate dielectric thickness of transistors forming LV circuits 404 may be larger than the gate dielectric thickness of transistors forming LLV circuits 402, but smaller than the gate dielectric thickness of transistors forming HV circuits 406.

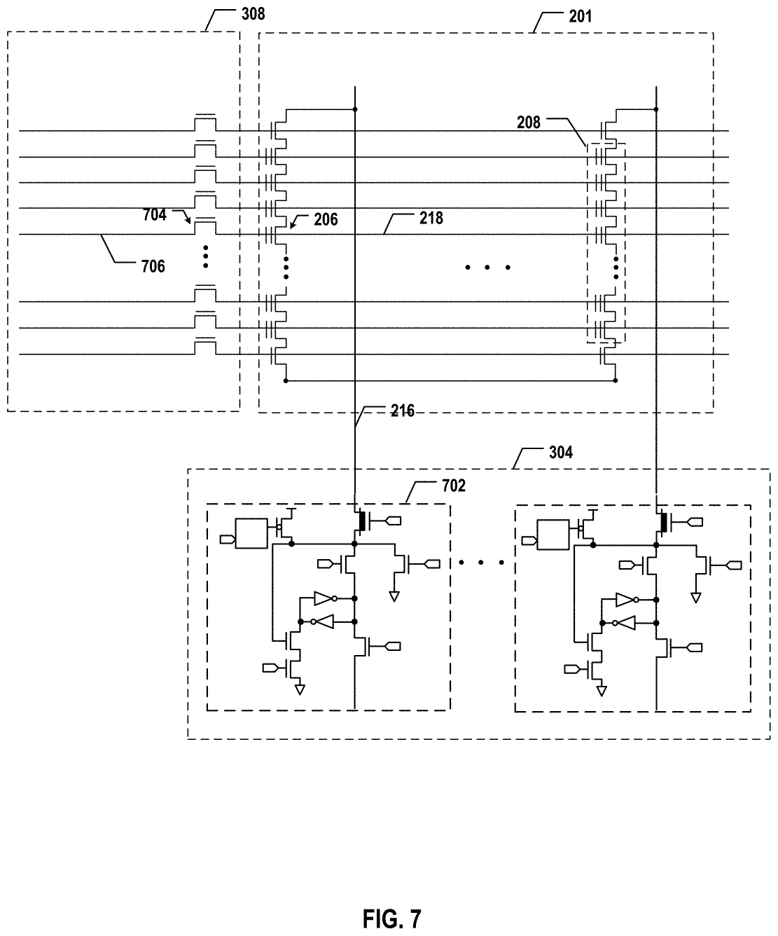

Based on the different performance requirements (e.g., associated with different applied voltages), peripheral circuits 202 can be separated into at least two stacked semiconductor structures 408 and 410 in different planes. In some implementations, the I/O circuits in interface 316 and/or data bus 318 (as LLV circuits 402) and logic circuits in control logic 312 (as part of LV circuits) are disposed in semiconductor structure 408, while the page buffer circuits in page buffer 304 and driving circuits in row decoder/word line driver 308 and column decoder/bit line driver 306 are disposed in semiconductor structure 410. For example, FIG. 7 illustrates a circuit diagram of word line driver 308 and page buffer 304, according to some aspects of the present disclosure.

In some implementations, page buffer 304 includes a plurality of page buffer circuits 702 each coupled to one NAND memory string 208 via a respective bit line 216. That is, memory device 200 can include bit lines 216 respectively coupled to NAND memory strings 208, and page buffer 304 can include page buffer circuits 702 respectively coupled to bit lines 216 and NAND memory strings 208. Each page buffer circuit 702 can include one or more latches, switches, supplies, nodes (e.g., data nodes and I/O nodes), current mirrors, verify logic, sense circuits, etc. In some implementations, each page buffer circuit 702 is configured to store sensing data corresponding to read data, which is received from a respective bit line 216, and output the stored sensing data to at the time of the read operation; each page buffer circuit 702 is also configured to store program data and output the stored program data to a respective bit line 216 at the time of the program operation.

In some implementations, word line driver 308 includes a plurality of string drivers 704 (a.k.a. driving circuits) respectively coupled to word lines 218. Word line driver 308 can also include a plurality of local word lines 706 (LWLs) respectively coupled to string drivers 704. Each string driver 704 can include a gate coupled to a decoder (not shown), a source/drain coupled to a respective local word line 706, and another source/drain coupled to a respective word line 218. In some memory operations, the decoder can select certain string drivers 704, for example, by applying a voltage signal greater than the threshold voltage of string drivers 704, and a voltage (e.g., program voltage, pass voltage, or erase voltage) to each local word line 706, such that the voltage is applied by each selected string driver 704 to a respective word line 218. In contrast, the decoder can also deselect certain string drivers 704, for example, by applying a voltage signal smaller than the threshold voltage of string drivers 704, such that each deselected string driver 704 floats a respective word line 218 during the memory operation.

In some implementations, page buffer circuits 702 include parts of LV circuits 404 disposed in semiconductor structures 408 and/or 410. In one example, since the number of page buffer circuits 702 increases as the number of bit numbers increases, which may occupy a large area for memory devices with large numbers of memory cells, page buffer circuits 702 may be split to semiconductor structures 408 and 410. In some implementations, string drivers 704 include parts of HV circuits 406 disposed in semiconductor structure 410.

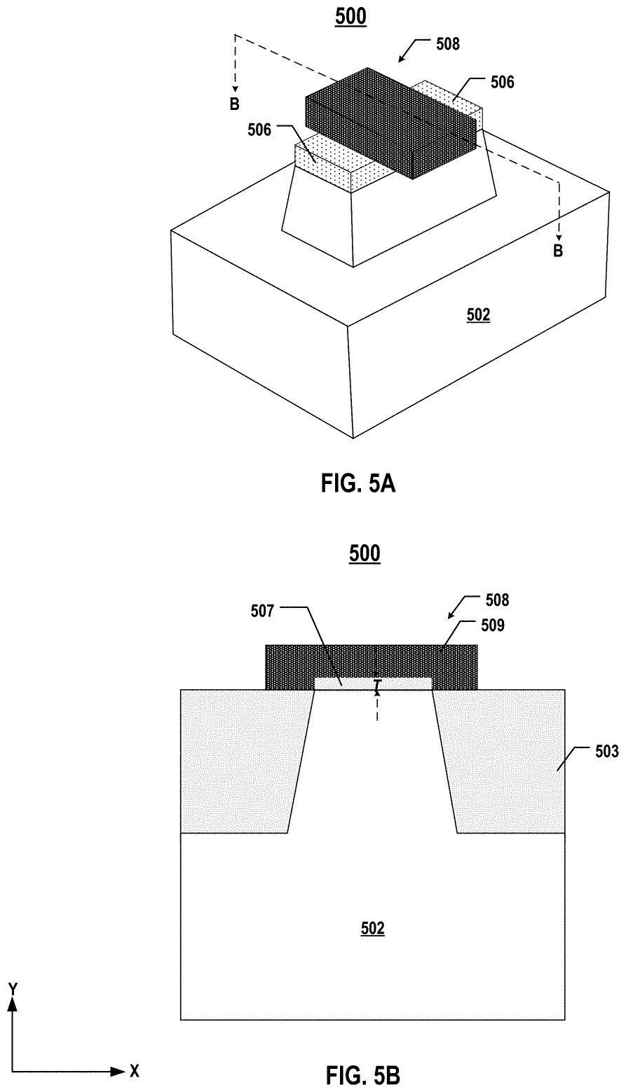

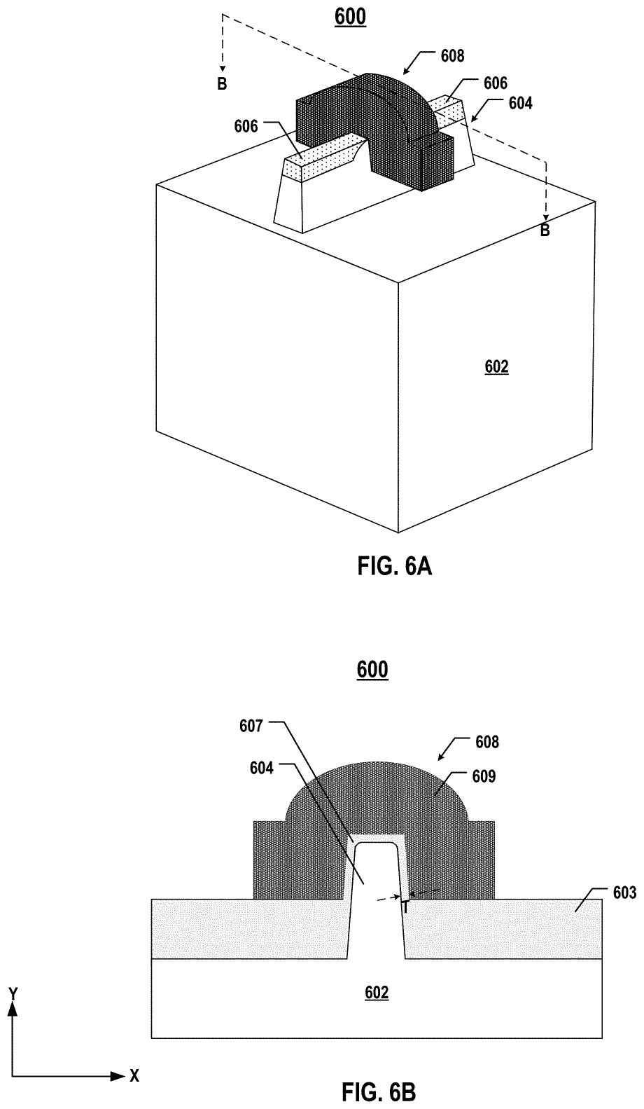

Consistent with the scope of the present disclosure. each peripheral circuit 202 can include a plurality of transistors as the basic building units thereof. The transistors can be metal-oxide-semiconductor field-effect-transistors (MOSFETs) in 2D (2D transistors, a.k.a. planar transistors) or 3D (3D transistors). For example, FIGS. 5A and 5B illustrate a perspective view and a side view, respectively, of a planar transistor 500, according to some aspects of the present disclosure, and FIGS. 6A and 6B illustrate a perspective view and a side view, respectively, of a 3D transistor 600, according to some aspects of the present disclosure. FIG. 5B illustrates the side view of the cross-section of planar transistor 500 in FIG. 5A in the BB plane, and FIG. 6B illustrates the side view of the cross-section of 3D transistor 600 in FIG. 6A in the BB plane.

As shown in FIGS. 5A and 5B, planar transistor 500 can be a MOSFET on a substrate 502, which can include silicon (e.g., single crystalline silicon, c-Si), SiGe, GaA), Ge, silicon-on-insulator (SOI), or any other suitable materials. Trench isolations 503, such as shallow trench isolations (STI), can be formed in substrate 502 and between adjacent planar transistors 500 to reduce current leakage. Trench isolations 503 can include any suitable dielectric materials, such as silicon oxide, silicon nitride, silicon oxynitride, or high dielectric constant (high-k) dielectrics (e.g., aluminum oxide, hafnium oxide, zirconium oxide, etc.). In some implementations, high-k dielectric materials include any dielectrics having a dielectric constant, or k-value, higher than that of silicon nitride (k>7). In some implementations, trench isolation 503 includes silicon oxide.

As shown in FIGS. 5A and 5B, planar transistor 500 can also include a gate structure 508 on substrate 502. In some implementations, gate structure 508 is on the top surface of substrate 502. As shown in FIG. 5B, gate structure 508 can include a gate dielectric 507 on substrate 502, i.e., above and in contact with the top surface of substrate 502. Gate structure 508 can also include a gate electrode 509 on gate dielectric 507, i.e., above and in contact with gate dielectric 507. Gate dielectric 507 can include any suitable dielectric materials, such as silicon oxide, silicon nitride, silicon oxynitride, or high-k dielectrics. In some implementations, gate dielectric 507 includes silicon oxide, i.e., a gate oxide. Gate electrode 509 can include any suitable conductive materials, such as polysilicon, metals (e.g., W, Cu, Al, etc.), metal compounds (e.g., TiN, TaN, etc.), or silicides. In some implementations, gate electrode 509 includes doped polysilicon, i.e., a gate poly.

As shown in FIG. 5A, planar transistor 500 can further include a pair of a source and a drain 506 in substrate 502. Source and drain 506 can be doped with any suitable P-type dopants, such as boron (B) or Gallium (Ga), or any suitable N-type dopants, such as phosphorus (P) or arsenic (As). Source and drain 506 can be separated by gate structure 508 in the plan view. In other words, gate structure 508 is formed between source and drain 506 in the plan view, according to some implementations. The channel of planar transistor 500 in substrate 502 can be formed laterally between source and drain 506 under gate structure 508 when a gate voltage applied to gate electrode 509 of gate structure 508 is above the threshold voltage of planar transistor 500. As shown in FIGS. 5A and 5B, gate structure 508 can be above and in contact with the top surface of the part of substrate 502 in which the channel can be formed (the active region). That is, gate structure 508 is in contact with only one side of the active region, i.e., in the plane of the top surface of substrate 502, according to some implementations. It is understood, although not shown in FIGS. 5A and 5B, planar transistor 500 may include additional components, such as wells and spacers.

As shown in FIGS. 6A and 6B, 3D transistor 600 can be a MOSFET on a substrate 602, which can include silicon (e.g., single crystalline silicon, c-Si), SiGe, GaAs, Ge, silicon on insulator SOI, or any other suitable materials. In some implementations, substrate 602 includes single crystalline silicon. Trench isolations 603, such as STI, can be formed in substrate 602 and between adjacent 3D transistors 600 to reduce current leakage. Trench isolations 603 can include any suitable dielectric materials, such as silicon oxide, silicon nitride, silicon oxynitride, or high-k dielectrics (e.g., aluminum oxide, hafnium oxide, zirconium oxide, etc.). In some implementations, trench isolation 603 includes silicon oxide.

As shown in FIGS. 6A and 6B, different from planar transistor 500, 3D transistor 600 can further include a 3D semiconductor body 604 above substrate 602. That is, in some implementations, 3D semiconductor body 604 at least partially extends above the top surface of substrate 602 to expose not only the top surface, but also the two side surfaces, of 3D semiconductor body 604. As shown in FIGS. 6A and 6B, for example, 3D semiconductor body 604 may be in a 3D structure, which is also known as a “fin,” to expose three sides thereof. 3D semiconductor body 604 is formed from substrate 602 and thus, has the same semiconductor material as substrate 602, according to some implementations. In some implementations, 3D semiconductor body 604 includes single crystalline silicon. Since the channels can be formed in 3D semiconductor body 604, as opposed to substrate 602, 3D semiconductor body 604 may be viewed as the active region for 3D transistor 600.

As shown in FIGS. 6A and 6B, 3D transistor 600 can also include a gate structure 608 on substrate 602. Different from planar transistors 500 in which gate structure 508 is in contact with only one side of the active region, i.e., in the plane of the top surface of substrate 502, gate structure 608 of 3D transistor 600 can be in contact with a plurality of sides of the active region, i.e., in multiple planes of the top surface and side surfaces of the 3D semiconductor body 604. In other words, the active region of 3D transistor 600, i.e., 3D semiconductor body 604, can be at least partially surrounded by gate structure 608.

Gate structure 608 can include a gate dielectric 607 over 3D semiconductor body 604, e.g., in contact with the top surface and two side surfaces of 3D semiconductor body 604. Gate structure 608 can also include a gate electrode 609 over and in contact with gate dielectric 607. Gate dielectric 607 can include any suitable dielectric materials, such as silicon oxide, silicon nitride, silicon oxynitride, or high-k dielectrics. In some implementations, gate dielectric 607 includes silicon oxide, i.e., a gate oxide. Gate electrode 609 can include any suitable conductive materials, such as polysilicon, metals (e.g., W, Cu, Al, etc.), metal compounds (e.g., TiN, TaN, etc.), or silicides. In some implementations, gate electrode 609 includes doped polysilicon, i.e., a gate poly.

As shown in FIG. 6A, 3D transistor 600 can further include a pair of a source and a drain 606 in 3D semiconductor body 604. Source and drain 606 can be doped with any suitable P-type dopants, such as B or Ga, or any suitable N-type dopants, such as P or Ar. Source and drain 606 can be separated by gate structure 608 in the plan view. In other words, gate structure 608 is formed between source and drain 606 in the plan view, according to some implementations. As a result, multiple channels of 3D transistor 600 in 3D semiconductor body 604 can be formed laterally between source and drain 606 surrounded by gate structure 608 when a gate voltage applied to gate electrode 609 of gate structure 608 is above the threshold voltage of 3D transistor 600. Different from planar transistor 500 in which only a single channel can be formed on the top surface of substrate 502, multiple channels can be formed on the top surface and side surfaces of 3D semiconductor body 604 in 3D transistor 600. In some implementations, 3D transistor 600 includes a multi-gate transistor. It is understood, although not shown in FIGS. 6A, and 6B, 3D transistor 600 may include additional components, such as wells, spacers, and stressors (a.k.a. strain elements) at source and drain 606.

It is further understood that FIGS. 6A and 6B illustrate one example of 3D transistors that can be used in memory peripheral circuits, and any other suitable 3D multi-gate transistors may be used in memory peripheral circuits as well, including, for example, a gate all around (GAA) silicon on nothing (SON) transistor, a multiple independent gate FET (MIGET), a trigate FET, a Π-gate FET, and a Ω-FET, a quadruple gate FET, a cylindrical FET, or a multi-bridge/stacked nanowire FET.

Regardless of planar transistor 500 or 3D transistor 600, each transistor a memory peripheral circuit can include a gate dielectric (e.g., gate dielectrics 507 and 607) having a thickness T (gate dielectric thickness, e.g., shown in FIGS. 5B and 6B). The gate dielectric thickness T of a transistor can be designed to accommodate the voltage applied to the transistor. For example, referring to FIGS. 4A and 4B, the gate dielectric thickness of transistors in HV circuits 406 (e.g., driving circuits such as string drivers 704) may be larger than the gate dielectric thickness of transistors in LV circuits 404 (e.g., page buffer circuits 702 or logic circuits in control logic 312), which may be in turn larger than the gate dielectric thickness of transistors in LLV circuits 402 (e.g., I/O circuits in interface 316 and data bus 318). In some implementations, the difference between the gate dielectric thickness of transistors in HV circuits 406 and the dielectric thickness of transistors in LLV circuits 402 is at least 5-fold, such as between 5-fold and 50-fold. For example, the gate dielectric thickness of transistors in HV circuits 406 may be at least 5 times larger than the gate dielectric thickness of transistors in LLV circuits 402.

In some implementations, the dielectric thickness of transistors in LLV circuits 402 is between 2 nm and 4 nm (e.g., 2 nm, 2.1 nm, 2.2 nm, 2.3 nm, 2.4 nm, 2.5 nm, 2.6 nm, 2.7 nm, 2.8 nm, 2.9 nm, 3 nm, 3.1 nm, 3.2 nm, 3.3 nm, 3.4 nm, 3.5 nm, 3.6 nm, 3.7 nm, 3.8 nm, 3.9 nm, 4 nm, any range bounded by the lower end by any of these values, or in any range defined by any two of these values). It is understood that the thickness may be commensurate with the LLV voltage range applied to LLV circuits 402, as described above in detail, such as below 1.3 V (e.g., 1.2 V). In some implementations, the dielectric thickness of transistors in LV circuits 404 is between 4 nm and 10 nm (e.g., 4 nm, 4.5 nm, 5 nm, 5.5 nm, 6 nm, 6.5 nm, 7 nm, 7.5 nm, 8 nm, 8.5 nm, 9 nm. 9.5 nm, 10 nm, any range bounded by the lower end by any of these values, or in any range defined by any two of these values). It is understood that the thickness may be commensurate with the LV voltage range applied to LV circuits 404, as described above in detail, such as between 1.3 V and 3.3 V (e.g., 3.3 V). In some implementations, the dielectric thickness of transistors in HV circuits 406 is between 20 nm and 100 nm (e.g., 20 nm, 21 nm, 22 nm, 23 nm, 24 nm, 25 nm, 26 nm, 27 nm, 28 nm, 29 nm, 30 nm, 31 nm, 32 nm, 33 nm, 34 nm, 35 nm, 36 nm, 37 nm, 38 nm, 39 nm, 40 nm, 45 nm, 50 nm, 55 nm, 60 nm, 65 nm, 70 nm, 75 nm, 80 nm, 85 nm, 90 nm, 95 nm, 100 nm, any range bounded by the lower end by any of these values, or in any range defined by any two of these values). It is understood that the thickness may be commensurate with the HV voltage range applied to HV circuits 406, as described above in detail, such as greater than 3.3 V (e.g., between 5 V and 30 V).

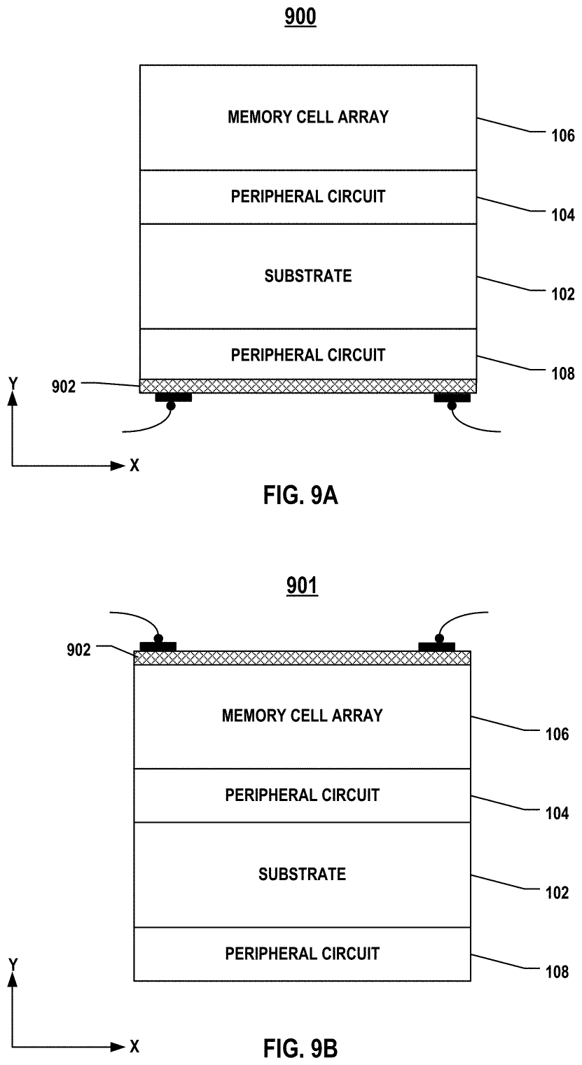

FIGS. 9A and 9B illustrate schematic views of cross-sections of 3D memory devices 900 and 901 having different pad-out structures, according to various aspects of the present disclosure. 3D memory devices 900 and 901 may be examples of 3D memory device 100 in FIG. 1 in which memory cell array 106 is formed above peripheral circuit 104, and peripheral circuit 104 and peripheral circuit 108 are formed on two sides of substrate 102. In some implementations, memory cell array 106 may include an array of NAND memory strings (e.g., NAND memory strings 208 disclosed herein), and the sources of the array of NAND memory strings can be in contact with semiconductor layer 805 (e.g., as shown in FIG. 8). Semiconductor layer 805 is formed between memory cell array 106 and peripheral circuit 104, and may include semiconductor materials, such as polysilicon (e.g., a deposited layer), for example, depending on the types of channel structures of the NAND memory strings (e.g., bottom open channel structure 812).

In some implementations, substrate 102 may include two opposite sides, e.g., the upper side and the bottom side, and peripheral circuit 104 is formed on the upper side of substrate 102 and peripheral circuit 108 is formed on the bottom side of substrate 102. That is, the transistors (e.g., planar transistors 500 and 3D transistors 600) of the first portion of the peripheral circuits and the transistors (e.g., planar transistors 500 and 3D transistors 600) of the second portion of the peripheral circuits can be in contact with opposite sides of substrate 102. Thus, the transistors of the two separate portions of the peripheral circuits are formed over each other in different planes across substrate 102, according to some implementations.

In some implementations, substrate 102 on which the transistors are formed may include single crystalline silicon, but not polysilicon, due to the superior carrier mobility of single crystalline silicon that is desirable for transistors' performance. Through contacts (e.g., interlayer vias (ILVs)/through substrate vias (TSVs)) through substrate 102 can make direct, short-distance (e.g., submicron-level) electrical connections between the two portions of the peripheral circuits (peripheral circuit 104 and peripheral circuit 108) on opposite sides of substrate 102. In some implementations, memory cell array 106 and peripheral circuit 104 are not combined with a bonding operation. Instead, semiconductor layer 805, e.g., a polysilicon material, may be formed on peripheral circuit 104, and memory cell array 106 is formed on semiconductor layer 805. The fabrication process will be described in detail below.

Moreover, as shown in FIGS. 9A and 9B, 3D memory device 900 or 901 may further include a pad-out interconnect layer 902 for pad-out purposes, i.e., interconnecting with external devices using contact pads on which bonding wires can be soldered. In one example shown in FIG. 9A, peripheral circuit 108 may include pad-out interconnect layer 902. In this example, 3D memory device 900 may be pad-out from the peripheral circuit side to reduce the interconnect distance between contact pads and the peripheral circuits, thereby decreasing the parasitic capacitance from the interconnects and improving the electrical performance of 3D memory device 900. In another example shown in FIG. 9B, memory cell array 106 may include pad-out interconnect layer 902.

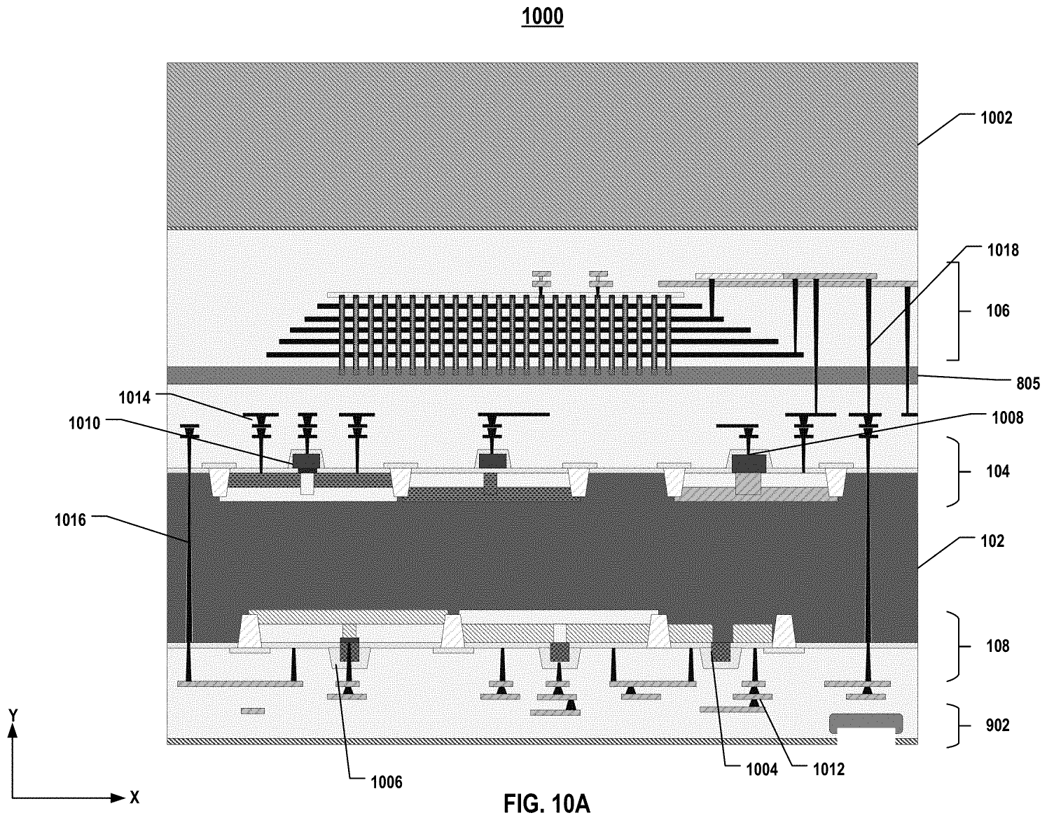

FIGS. 10A and 10B illustrate side views of various examples of 3D memory devices 900 and 901 in FIGS. 9A and 9B, according to various aspects of the present disclosure. As shown in FIG. 10A, as one example of 3D memory device 900 in FIG. 9A, 3D memory device 1000 is a semiconductor structure including substrate 102, peripheral circuit 104, memory cell array 106, and peripheral circuit 108, which are formed over each other in different planes in the vertical direction (e.g., the y-direction in FIG. 10A), according to some implementations.

In some implementations, substrate 102 is a silicon substrate having single crystalline silicon. Devices, such as transistors, can be formed on both sides of substrate 102. In some implementations, the thickness of substrate 102 is between 1 μm and 10 μm. Peripheral circuit 108 is below and in contact with a first side (e.g., toward the negative y-direction in FIG. 10A) of substrate 102.

In some implementations, peripheral circuit 108 may include a device circuit 1004 and a device circuit 1006. Device circuit 1004 can include LLV circuits 402, such as I/O circuits (e.g., in interface 316 and data bus 318), and device circuit 1006 can include LV circuits 404, such as page buffer circuits (e.g., page buffer circuits 702 in page buffer 304) and logic circuits (e.g., in control logic 312). In some implementations, device circuit 1004 includes a plurality of transistors in contact with the first side of substrate 102, and device circuit 1006 includes a plurality of transistors in contact with the first side of substrate 102. The transistors can include any transistors disclosed herein, such as planar transistors 500 and 3D transistors 600. As described above in detail with respect to transistors 500 and 600, in some implementations, each transistor includes a gate dielectric, and the thickness of the gate dielectric of LLV transistor (e.g., in LLV circuit 402) is smaller than the thickness of the gate dielectric of LV transistor (e.g., in LV circuit 404) due to the lower voltage applied to the LLV transistors. Trench isolations (e.g., STIs) and doped regions (e.g., wells, sources, and drains of the transistors) can be formed on the first side of substrate 102 as well.

In some implementations, peripheral circuit 108 further includes an interconnect layer 1012 under device circuit 1004 and device circuit 1006 to transfer electrical signals to and from peripheral circuit 108. As shown in FIG. 10A, device circuit 1004 and device circuit 1006 may be disposed vertically between substrate 102 and interconnect layer 1012. Interconnect layer 1012 may include a plurality of interconnects. The interconnects in interconnect layer 1012 may be coupled to the transistors of device circuit 1004 and device circuit 1006. Interconnect layer 1012 may further include one or more interlayer dielectric (ILD) layers in which the lateral lines and vias can form. That is, interconnect layer 1012 may include lateral lines and vias in multiple ILD layers. In some implementations, the devices in peripheral circuit 108 are coupled to one another through the interconnects in interconnect layer 1012. For example, device circuit 1004 may be coupled to device circuit 1006 through interconnect layer 1012. The interconnects in interconnect layer 1012 may include conductive materials including, but not limited to, W, Co, Cu, Al, silicides, or any combination thereof. The ILD layers in interconnect layer 1012 can include dielectric materials including, but not limited to, silicon oxide, silicon nitride, silicon oxynitride, low-k dielectrics, or any combination thereof.

In some implementations, the interconnects in interconnect layer 1012 include Cu, which has a relatively low resistivity (better electrical performance) among conductive metal materials. As described below with respect to the fabrication process, although Cu has a relatively low thermal budget (incompatible with high-temperature processes), since the fabrication of interconnect layer 1012 may occur after the high-temperature processes in forming peripheral circuit 104, peripheral circuit 108, and memory cell array 106, the interconnects of interconnect layer 1012 having Cu can become feasible.

In some implementations, peripheral circuit 104 may be formed on and in contact with a second side (e.g., toward the positive y-direction in FIG. 10A) of substrate 102 opposite to the first side. Peripheral circuit 104 and peripheral circuit 108 can thus be disposed in different planes in the vertical direction, i.e., formed over one another on opposite sides of substrate 102.

In some implementations, peripheral circuit 104 may include a device circuit 1008 and a device circuit 1010. Device circuit 1008 may include HV circuits, such as driving circuits (e.g., string drivers 704 in row decoder/word line driver 308 and drivers in column decoder/bit line driver 306), and device circuit 1010 may include LV circuits, such as page buffer circuits (e.g., page buffer circuits 702 in page buffer 304) and logic circuits (e.g., in control logic 312). In some implementations, device circuit 1008 includes a plurality of transistors, and device circuit 1010 includes a plurality of transistors as well. The transistors may include any transistors disclosed herein, such as planar transistors 500 and 3D transistors 600. As described above in detail with respect to transistors 500 and 600, in some implementations, each transistor includes a gate dielectric, and the thickness of the gate dielectric of HV transistor (e.g., in HV circuit 406) is larger than the thickness of the gate dielectric of LV transistor (e.g., in LV circuit 404) due to the higher voltage applied to HV transistor. In some implementations, the thickness of the gate dielectric of HV transistor (e.g., in HV circuit 406) is larger than the thickness of the gate dielectric of LLV transistor (e.g., in LLV circuit 402) due to the higher voltage applied to HV transistor than LLV transistor. Trench isolations (e.g., STIs) and doped regions (e.g., wells, sources, and drains of the transistors) can be formed on the second side of substrate 102 as well.

As shown in FIG. 10A, peripheral circuit 104 may further include an interconnect layer 1014 on device circuit 1008 and device circuit 1010 to transfer electrical signals to and from device circuit 1008 and device circuit 1010. As shown in FIG. 10A, interconnect layer 1014 may be vertically between semiconductor layer 805 and peripheral circuit 104. Interconnect layer 1014 may include a plurality of interconnects coupled to the transistors of device circuit 1008 and device circuit 1010. Interconnect layer 1014 may further include one or more ILD layers in which the interconnects can form. That is, interconnect layer 1014 can include lateral lines and vias in multiple ILD layers. In some implementations, the devices in device circuit 1008 and device circuit 1010 are coupled to one another through the interconnects in interconnect layer 1014. For example, device circuit 1008 may be coupled to device circuit 1010 through interconnect layer 1014. The interconnects in interconnect layer 1014 may include conductive materials including, but not limited to, W, Co, Cu, Al, silicides, or any combination thereof. The ILD layers in interconnect layer 1014 may include dielectric materials including, but not limited to, silicon oxide, silicon nitride, silicon oxynitride, low-k dielectrics, or any combination thereof. In some implementations, the interconnects in interconnect layer 1014 include W, which has a relatively high thermal budget (compatible with high-temperature processes) and good quality (fewer detects, e.g., voids) among conductive metal materials.

As shown in FIG. 10A, 3D memory device 1000 may further include one or more contacts 1016 extending vertically through substrate 102. In some implementations, contacts 1016 couples the interconnects in interconnect layer 1012 to the interconnects in interconnect layer 1014 to make an electrical connection between opposite sides of substrate 102. Contact 1016 may include conductive materials including, but not limited to, W, Co, Cu, Al, silicides, or any combination thereof. In some implementations, contact 1016 includes a via surrounded by a dielectric spacer (e.g., having silicon oxide) to electrically separate the via from substrate 102. Depending on the thickness of substrate 102, contact 1016 may be an inter layers via (ILV) having a depth in the submicron-level (e.g., between 10 nm and 1 μm), or a through silicon via (TSV) having a depth in the micron- or tens micron-level (e.g., between 1 μm and 100 μm).

As shown in FIG. 10A, semiconductor layer 805 is formed on interconnect layer 1014, and memory cell array 106 is formed on semiconductor layer 805. In some implementations, semiconductor layer 805 is formed over the ILD layer. In some implementations, semiconductor layer 805 may include polysilicon materials. In some implementations, semiconductor layer 805 may include doped polysilicon, doped amorphous silicon, and/or doped single-crystalline silicon and can be formed by any suitable deposition methods such chemical vapor deposition (CVD), physical vapor deposition (PVD), atomic layer deposition (ALD), plasma enhanced CVD (PECVD), low pressure CVD (LPCVD), or any combination thereof.

Memory cell array 106, such as an array of NAND memory strings, and contacts 1018 are formed on semiconductor layer 805. In some implementations, each NAND memory string extends vertically through a plurality of pairs each including a conductive layer and a dielectric layer. The stacked and interleaved conductive layers and dielectric layers are also referred to herein as a stack structure, e.g., a memory stack. The memory stack may be an example of memory stack 804 in FIG. 8, and the conductive layer and dielectric layer in the memory stack may be examples of gate conductive layers 806 and dielectric layer 808, respectively, in memory stack 804. The interleaved conductive layers and dielectric layers in the memory stack alternate in the vertical direction, according to some implementations. Each conductive layer can include a gate electrode (gate line) surrounded by an adhesive layer and a gate dielectric layer. The gate electrode of the conductive layer can extend laterally as a word line, ending at one or more staircase structures of the memory stack. In some implementations, each NAND memory string is a “charge trap” type of NAND memory string including any suitable channel structures disclosed herein, such as bottom open channel structure 812, described above in detail with respect to FIG. 8.

As shown in FIG. 10A, 3D memory device 1000 may further include pad-out interconnect layer 902 for pad-out purposes, i.e., interconnecting with external devices using contact pads on which bonding wires can be soldered. Pad-out interconnect layer 902 may be under and in contact with interconnect layer 1012. Pad-out interconnect layer 902 may include interconnects, e.g., contact pads, in one or more ILD layers. Pad-out interconnect layer 902 and interconnect layer 1012 may be formed on the same side of 3D memory device 1000. In some implementations, the interconnects in pad-out interconnect layer 902 can transfer electrical signals between 3D memory device 1000 and external devices, e.g., for pad-out purposes.

As shown in FIG. 10A, 3D memory device 1000 may include a carrier substrate 1002 on memory cell array 106. In some implementations, carrier substrate 1002 may be bonded on memory cell array 106 after the formation of memory cell array 106. When 3D memory device 1000 is flipped over to perform the fabrication processes of peripheral circuit 108 and pad-out interconnect layer 902, carrier substrate 1002 may provide the support of 3D memory device 1000.

As a result, device circuit 1004, device circuit 1006, device circuit 1008, and device circuit 1010 on different sides of substrate 102 can be coupled to NAND memory strings in memory cell array 106 through various interconnection structures, including interconnect layers 1012 and 1014, as well as contacts 1016 and 1018. Moreover, device circuit 1004, device circuit 1006, device circuit 1008, device circuit 1010, and memory cell array 106 can be further coupled to external devices through pad-out interconnect layer 902.

It is understood that the pad-out of 3D memory devices is not limited to from peripheral circuit 108 as shown in FIG. 10A (corresponding to FIG. 9A) and may be from memory cell array 106 (corresponding to FIG. 9B). For example, as shown in FIG. 10B, 3D memory device 1001 may include pad-out interconnect layer 904 above memory cell array 106.

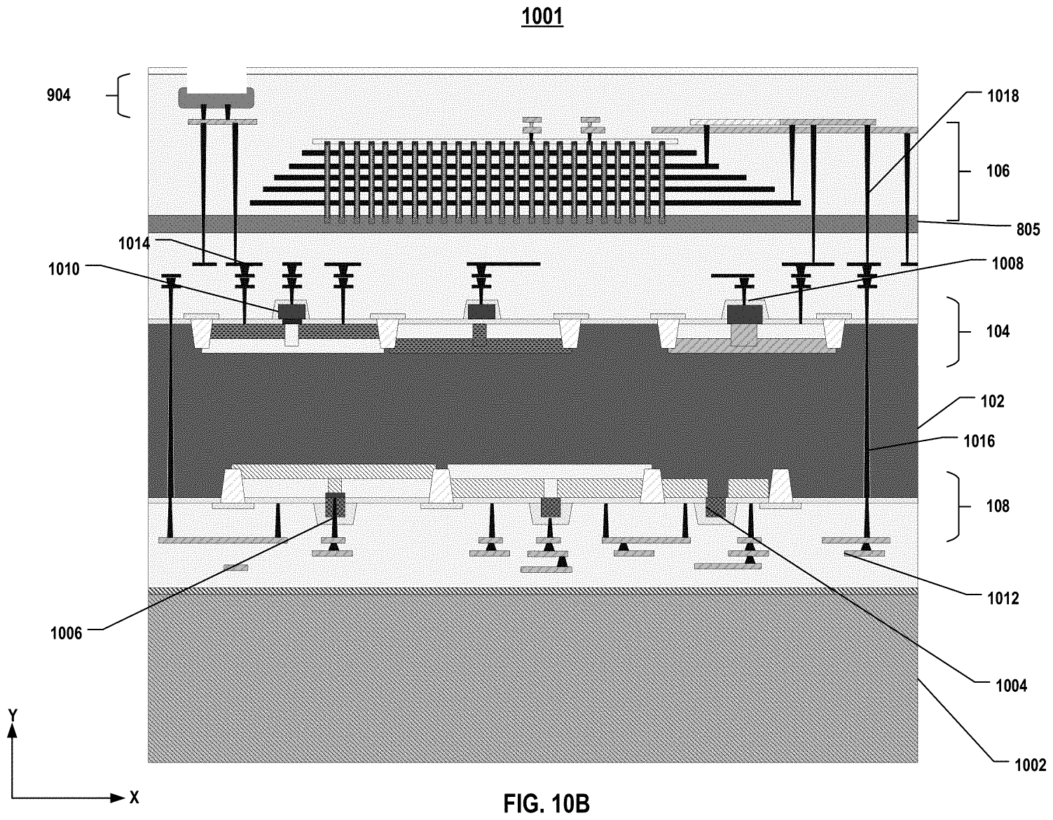

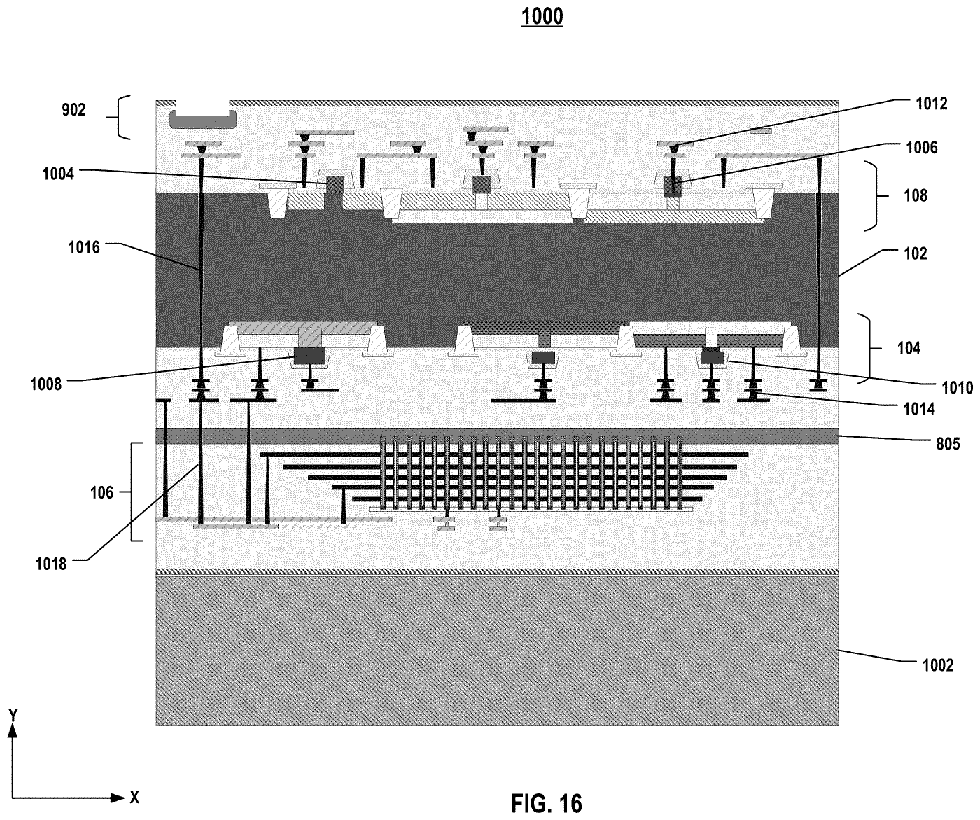

FIGS. 11-16 illustrate a fabrication process for forming the 3D memory devices in FIG. 10A, according to some aspects of the present disclosure. FIG. 17 illustrates a flowchart of a method 1700 for forming the 3D memory devices in FIGS. 11-16, according to some aspects of the present disclosure. For the purpose of better describing the present disclosure, the cross-sections of 3D memory device 1000 in FIGS. 11-16 and method 1700 in FIG. 17 will be described together. It is understood that the operations shown in method 1700 are not exhaustive and that other operations may be performed as well before, after, or between any of the illustrated operations. Further, some of the operations may be performed simultaneously, or in a different order than shown in FIGS. 11-16 and FIG. 17.

As shown in FIG. 11 and operation 1702 in FIG. 17, peripheral circuit 104 is formed on a first side of substrate 102. In some implementations, a plurality of transistors are formed on the first side of substrate 102. Substrate 102 may be a silicon substrate having single crystalline silicon. The transistors (device circuit 1008 and device circuit 1010) are formed on one side of substrate 102. The transistors may be formed by a plurality of processes including, but not limited to, photolithography, dry/wet etch, thin film deposition, thermal growth, implantation, chemical mechanical polishing (CMP), and any other suitable processes. In some implementations, doped regions are formed in substrate 102 by ion implantation and/or thermal diffusion, which function, for example, as wells and source/drain regions of the transistors. In some implementations, isolation regions (e.g., STIs) are also formed in substrate 102 by wet/dry etch and thin film deposition. In some implementations, the thickness of gate dielectric of transistors of device circuit 1008 may be different from the thickness of gate dielectric of transistors of device circuit 1010. For example, by depositing a thicker silicon oxide film in the region of device circuit 1008 than the region of device circuit 1010, or by etching back part of the silicon oxide film deposited in the region of device circuit 1010. It is understood that the details of fabricating the transistors may vary depending on the types of the transistors (e.g., planar transistors 500 or 3D transistors 600 in FIGS. 5A, 5B, 6A, and 6B) and thus, are not elaborated for ease of description.

In some implementations, interconnect layer 1014 is formed above the transistors on substrate 102. Interconnect layer 1014 can include a plurality of interconnects in one or more ILD layers. Interconnect layer 1014 may include interconnects of middle-end-of-line (MEOL) interconnects and/or back-end-of-line (BEOL) interconnects in a plurality of ILD layers to make electrical connections with the transistors.

In some implementations, interconnect layer 1014 includes multiple ILD layers and interconnects therein formed in multiple processes. For example, the interconnects in interconnect layer 1014 may include conductive materials deposited by one or more thin film deposition processes including, but not limited to, CVD, PVD, ALD, electroplating, electroless plating, or any combination thereof. Fabrication processes to form interconnects can also include photolithography, CMP, wet/dry etch, or any other suitable processes. The ILD layers can include dielectric materials deposited by one or more thin film deposition processes including, but not limited to, CVD, PVD, ALD, or any combination thereof. In some implementations, the interconnects in interconnect layer 1014 include W, which has a relatively high thermal budget among conductive metal materials to sustain later high-temperature processes.

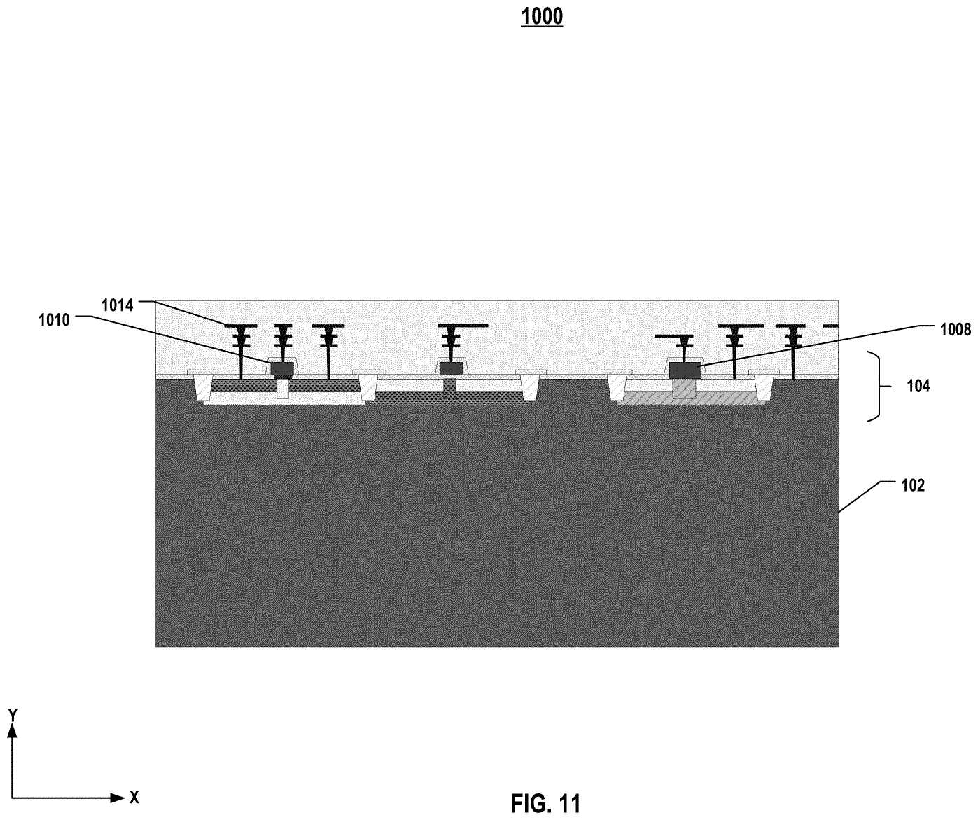

As shown in FIG. 12 and operation 1704 in FIG. 17, semiconductor layer 805 is formed over interconnect layer 1014. In some implementations, a polysilicon layer may be formed by using a thin film deposition process, such as LPCVD, PECVD, ALD or any other suitable processes.

As shown in FIG. 12 and operation 1706 in FIG. 17, memory cell array 106 is formed on semiconductor layer 805. In some implementations, a stack structure, such as a memory stack including interleaved conductive layers and dielectric layers, is formed on semiconductor layer 805. To form the memory stack, in some implementations, a dielectric stack (not shown) including interleaved sacrificial layers (not shown) and the dielectric layers is formed on semiconductor layer 805. In some implementations, each sacrificial layer includes a layer of silicon nitride, and each dielectric layer includes a layer of silicon oxide. The interleaved sacrificial layers and dielectric layers can be formed by one or more thin film deposition processes including, but not limited to, CVD, PVD, ALD, or any combination thereof. The memory stack can then be formed by a gate replacement process, e.g., replacing the sacrificial layers with the conductive layers using wet/dry etch of the sacrificial layers selective to the dielectric layers and filling the resulting recesses with the conductive layers. In some implementations, each conductive layer includes a metal layer, such as a layer of W. It is understood that the memory stack may be formed by alternatingly depositing conductive layers (e.g., doped polysilicon layers) and dielectric layers (e.g., silicon oxide layers) without the gate replacement process in some examples.

The NAND memory strings are formed above semiconductor layer 805, each of which extends vertically through the memory stack to be in contact with semiconductor layer 805. In some implementations, fabrication processes to form the NAND memory string include forming a channel hole through the memory stack (or the dielectric stack) and into semiconductor layer 805 using dry etching/and or wet etching, such as DRIE, followed by subsequently filling the channel hole with a plurality of layers, such as a memory film (e.g., a tunneling layer, a storage layer, and a blocking layer) and a semiconductor layer, using thin film deposition processes such as ALD, CVD, PVD, or any combination thereof. It is understood that the details of fabricating the NAND memory strings may vary depending on the types of channel structures of the NAND memory strings (e.g., bottom open channel structure 812 in FIG. 8) and thus, are not elaborated for ease of description.

In some implementations, an interconnect layer is formed above the array of NAND memory strings. The interconnect layer can include a plurality of interconnects in one or more ILD layers. The interconnect layer may include interconnects of MEOL and/or BEOL in a plurality of ILD layers to make electrical connections with the NAND memory strings. In some implementations, the interconnect layer includes multiple ILD layers and interconnects therein formed in multiple processes. For example, the interconnects in the interconnect layer may include conductive materials deposited by one or more thin film deposition processes including, but not limited to, CVD, PVD, ALD, electroplating, electroless plating, or any combination thereof. Fabrication processes to form interconnects can also include photolithography, CMP, wet/dry etch, or any other suitable processes. The ILD layers can include dielectric materials deposited by one or more thin film deposition processes including, but not limited to, CVD, PVD, ALD, or any combination thereof.

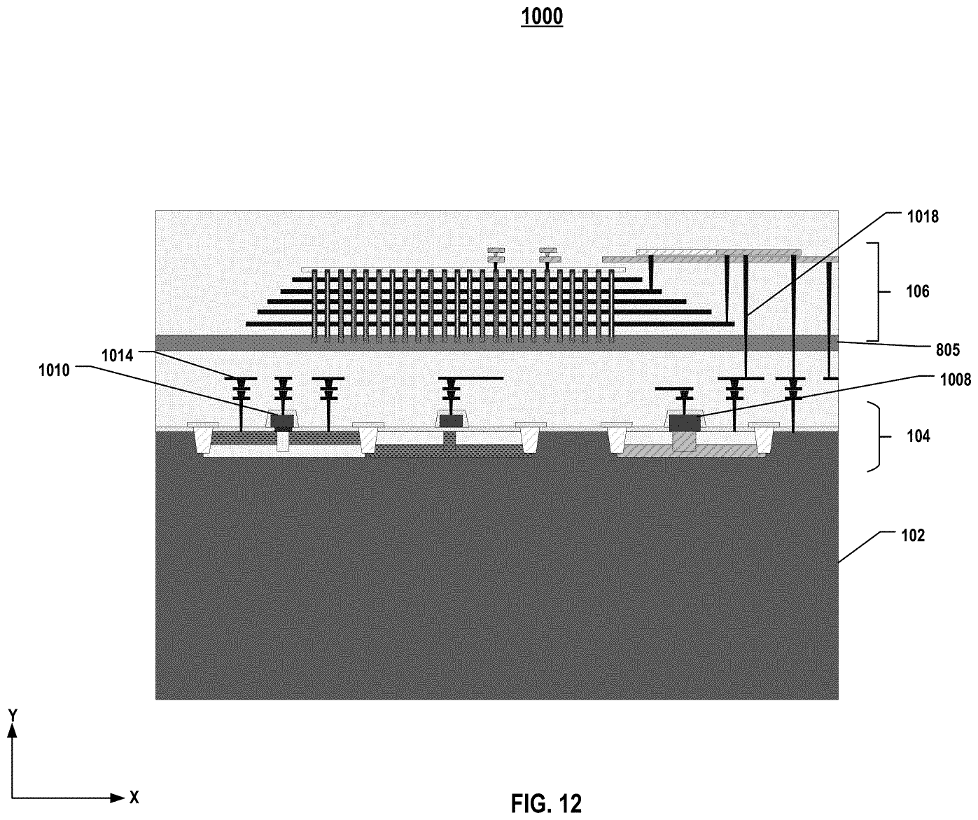

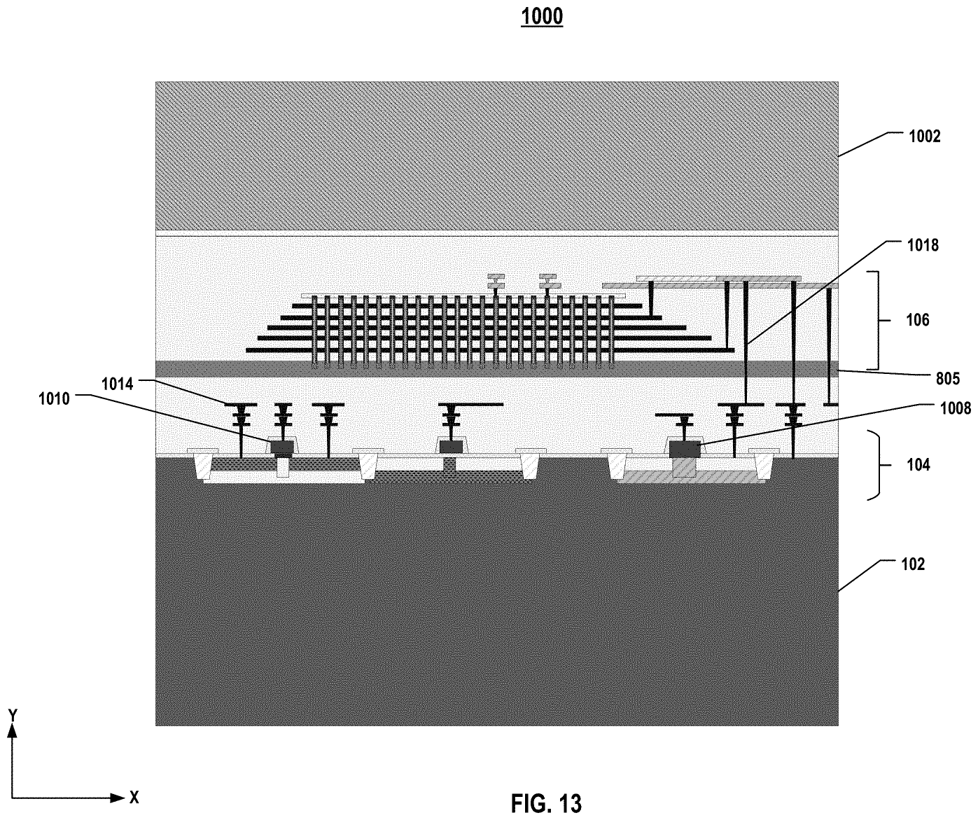

As shown in FIG. 13, after forming memory cell array 106, carrier substrate 1002 may be boned on memory cell array 106. In the following operations, when 3D memory device 1000 is flipped over to perform the fabrication processes of peripheral circuit 108 and pad-out interconnect layer 902, carrier substrate 1002 may provide the support of 3D memory device 1000. Then, as shown in FIG. 14, 3D memory device 1000 is flipped over. In some implementations, a thinning process may be performed on a second side of substrate 102 to thin substrate 102 to a required thickness. The second side is opposite to the first side of substrate 102 on which peripheral circuit 104 is formed. In some implementations, substrate 102 may be thinned by processes including, but not limited to, wafer grinding, dry etch, wet etch, CMP, any other suitable processes, or any combination thereof.

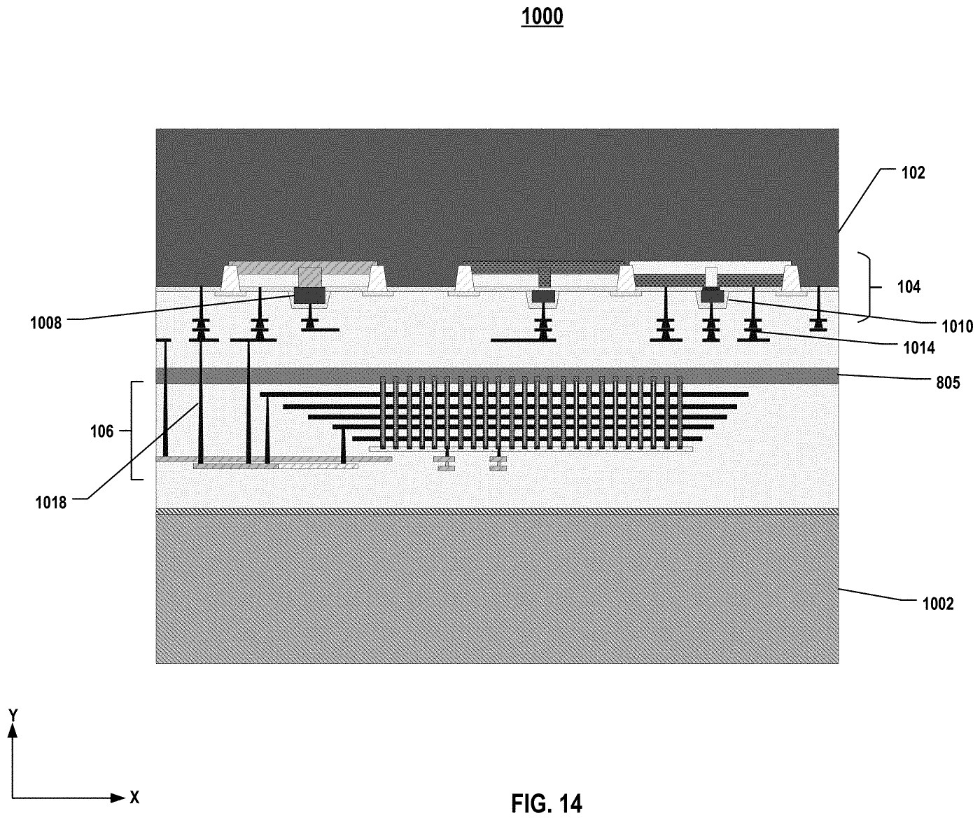

As shown in FIG. 15 and operation 1708 in FIG. 17, peripheral circuit 108 is formed on the second side of substrate 102 opposite to the first side. In some implementations, a plurality of transistors are formed on the second side of substrate 102. The transistors (device circuit 1004 and device circuit 1006) are formed on the second side of substrate 102. The transistors can be formed by a plurality of processes including, but not limited to, photolithography, dry/wet etch, thin film deposition, thermal growth, implantation, CMP, and any other suitable processes. In some implementations, doped regions are formed on the second side of substrate 102 by ion implantation and/or thermal diffusion, which function, for example, as wells and source/drain regions of the transistors. In some implementations, isolation regions (e.g., STIs) are also formed on the second side of substrate 102 by wet/dry etch and thin film deposition. In some implementations, the thickness of gate dielectric of the transistors of device circuit 1004 may be different from the thickness of gate dielectric of the transistors of device circuit 1006, for example, by depositing a thicker silicon oxide film in the region of device circuit 1004 than the region of device circuit 1006, or by etching back part of the silicon oxide film deposited in the region of device circuit 1006. It is understood that the details of fabricating the transistors may vary depending on the types of the transistors (e.g., planar transistors 500 or 3D transistors 600 in FIGS. 5A, 5B, 6A, and 6B) and thus, are not elaborated for ease of description.

In some implementations, interconnect layer 1012 is formed above the transistors. Interconnect layer 1012 may include a plurality of interconnects in one or more ILD layers. Interconnect layer 1012 may include interconnects of MEOL and/or BEOL in a plurality of ILD layers to make electrical connections with device circuit 1004 and device circuit 1006. In some implementations, interconnect layer 1012 includes multiple ILD layers and interconnects therein formed in multiple processes. For example, the interconnects in interconnect layer 1012 may include conductive materials deposited by one or more thin film deposition processes including, but not limited to, CVD, PVD, ALD, electroplating, electroless plating, or any combination thereof. Fabrication processes to form interconnects can also include photolithography, CMP, wet/dry etch, or any other suitable processes. The ILD layers can include dielectric materials deposited by one or more thin film deposition processes including, but not limited to, CVD, PVD, ALD, or any combination thereof.

Different from interconnect layer 1014, in some implementations, the interconnects in interconnect layer 1012 include Cu, which has a relatively low resistivity among conductive metal materials. It is understood that although Cu has a relatively low thermal budget (incompatible with high-temperature processes), using Cu as the conductive materials of the interconnects in interconnect layer 1012 may become feasible since there are no more high-temperature processes after the fabrication of interconnect layer 1012.

In some implementations, a contact through the thinned substrate is formed. As illustrated in FIG. 15, one or more contacts 1016 each extending vertically through substrate 102 are formed. Contacts 1016 may couple the interconnects in interconnect layer 1012 and the interconnects in interconnect layer 1014. Contact 1016 may be formed by first patterning contact holes through substrate 102 using patterning process (e.g., photolithography and dry/wet etch of dielectric materials in the dielectric layer). The contact holes can be filled with a conductor (e.g., W or Cu). In some implementations, filling the contact holes includes depositing a spacer (e.g., a silicon oxide layer) before depositing the conductor.

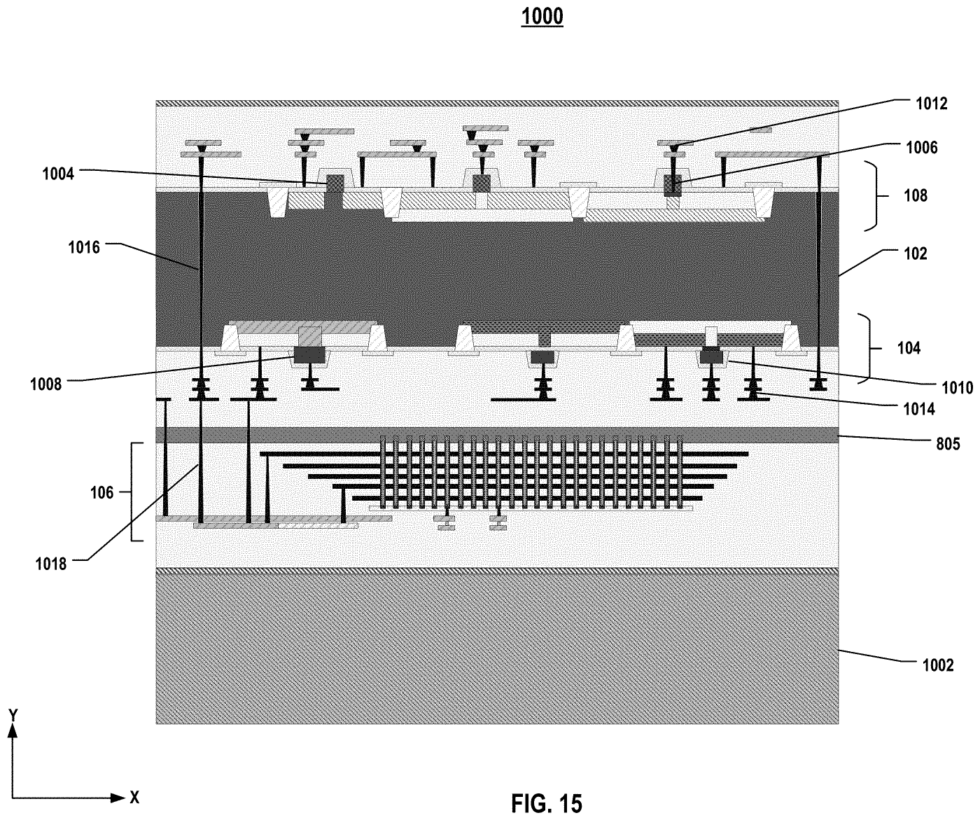

As shown in FIG. 16, pad-out interconnect layer 902 may be formed above interconnect layer 1012. Pad-out interconnect layer 902 may include interconnects, such as contact pads, formed in one or more ILD layers. The contact pads may include conductive materials including, but not limited to, W, Co, Cu, Al, doped silicon, silicides, or any combination thereof. The ILD layers can include dielectric materials including, but not limited to, silicon oxide, silicon nitride, silicon oxynitride, low-k dielectrics, or any combination thereof.

By forming 3D memory device 1000 with the above operations, a first layer of memory peripheral circuits may be formed on the first side of the substrate, and the memory cell array may be formed on the memory peripheral circuits on the same side of the substrate. Then the substrate may be flipped over and thinned, and a second layer of memory peripheral circuits may be formed on the second side of the substrate opposite to the first side. As a result, the fabrication size of the memory peripheral circuits may be doubled on one substrate to reduce the chip size and the manufacturing cost. Further, the second layer of memory peripheral circuits may be the low-voltage memory peripheral circuits provided with a relatively low voltage (e.g., below 1.3 V), and may be formed after the fabrication of the memory cell array. Hence, the low-voltage memory peripheral circuits will not be affected by the high temperature during the manufacturing of the memory cell array. In addition, the channel length of the low-voltage memory peripheral circuits can be reduced, and the input/output (I/O) speed of the memory devices can be improved as well. In some implementations, the minimality of the channel length of the low-voltage memory peripheral circuits can be further achieved.

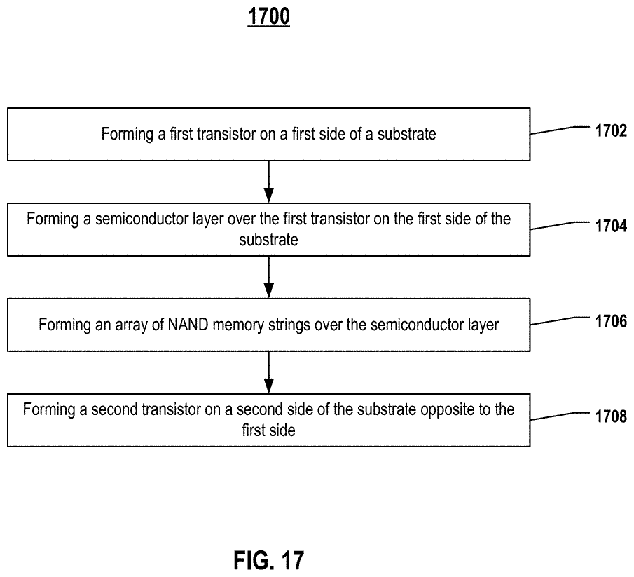

FIGS. 18-23 illustrate a fabrication process for forming the 3D memory devices in FIG. 10B, according to some aspects of the present disclosure. The fabrication process in FIGS. 18-23 may be similar to the fabrication process in FIGS. 11-16, but the pad-out of 3D memory devices is from memory cell array side.

As shown in FIG. 18, peripheral circuit 104 is formed on a first side of substrate 102. In some implementations, a plurality of transistors are formed on the first side of substrate 102. Substrate 102 may be a silicon substrate having single crystalline silicon. The transistors (device circuit 1008 and device circuit 1010) are formed on one side of substrate 102. The transistors may be formed by a plurality of processes including, but not limited to, photolithography, dry/wet etch, thin film deposition, thermal growth, implantation, CMP, and any other suitable processes. In some implementations, doped regions are formed in substrate 102 by ion implantation and/or thermal diffusion, which function, for example, as wells and source/drain regions of the transistors. In some implementations, isolation regions (e.g., STIs) are also formed in substrate 102 by wet/dry etch and thin film deposition. In some implementations, the thickness of gate dielectric of transistors of device circuit 1008 may be different from the thickness of gate dielectric of transistors of device circuit 1010. For example, by depositing a thicker silicon oxide film in the region of device circuit 1008 than the region of device circuit 1010, or by etching back part of the silicon oxide film deposited in the region of device circuit 1010. It is understood that the details of fabricating the transistors may vary depending on the types of the transistors (e.g., planar transistors 500 or 3D transistors 600 in FIGS. 5A, 5B, 6A, and 6B) and thus, are not elaborated for ease of description.

In some implementations, interconnect layer 1014 is formed above the transistors on substrate 102. Interconnect layer 1014 can include a plurality of interconnects in one or more ILD layers. Interconnect layer 1014 may include interconnects of MEOL interconnects and/or BEOL interconnects in a plurality of ILD layers to make electrical connections with the transistors.

In some implementations, interconnect layer 1014 includes multiple ILD layers and interconnects therein formed in multiple processes. For example, the interconnects in interconnect layer 1014 may include conductive materials deposited by one or more thin film deposition processes including, but not limited to, CVD, PVD, ALD, electroplating, electroless plating, or any combination thereof. Fabrication processes to form interconnects can also include photolithography, CMP, wet/dry etch, or any other suitable processes. The ILD layers can include dielectric materials deposited by one or more thin film deposition processes including, but not limited to, CVD, PVD, ALD, or any combination thereof. In some implementations, the interconnects in interconnect layer 1014 include W, which has a relatively high thermal budget among conductive metal materials to sustain later high-temperature processes.

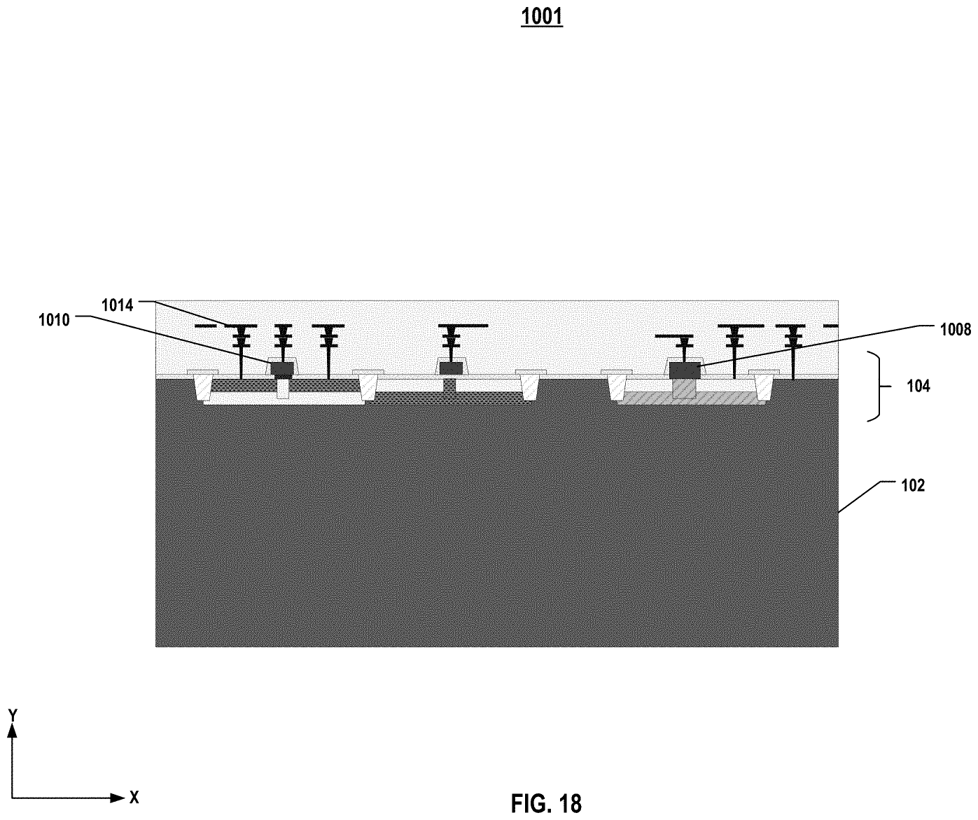

As shown in FIG. 19, semiconductor layer 805 is formed over interconnect layer 1014. In some implementations, a polysilicon layer may be formed by using a thin film deposition process, such as LPCVD, PECVD, ALD or any other suitable processes. Memory cell array 106 is formed on semiconductor layer 805. In some implementations, a stack structure, such as a memory stack including interleaved conductive layers and dielectric layers, is formed on semiconductor layer 805. To form the memory stack, in some implementations, a dielectric stack (not shown) including interleaved sacrificial layers (not shown) and the dielectric layers is formed on semiconductor layer 805. In some implementations, each sacrificial layer includes a layer of silicon nitride, and each dielectric layer includes a layer of silicon oxide. The interleaved sacrificial layers and dielectric layers can be formed by one or more thin film deposition processes including, but not limited to, CVD, PVD, ALD, or any combination thereof. The memory stack can then be formed by a gate replacement process, e.g., replacing the sacrificial layers with the conductive layers using wet/dry etch of the sacrificial layers selective to the dielectric layers and filling the resulting recesses with the conductive layers. In some implementations, each conductive layer includes a metal layer, such as a layer of W. It is understood that the memory stack may be formed by alternatingly depositing conductive layers (e.g., doped polysilicon layers) and dielectric layers (e.g., silicon oxide layers) without the gate replacement process in some examples.

The NAND memory strings are formed above semiconductor layer 805, each of which extends vertically through the memory stack to be in contact with semiconductor layer 805. In some implementations, fabrication processes to form the NAND memory string include forming a channel hole through the memory stack (or the dielectric stack) and into semiconductor layer 805 using dry etching/and or wet etching, such as DRIE, followed by subsequently filling the channel hole with a plurality of layers, such as a memory film (e.g., a tunneling layer, a storage layer, and a blocking layer) and a semiconductor layer, using thin film deposition processes such as ALD, CVD, PVD, or any combination thereof. It is understood that the details of fabricating the NAND memory strings may vary depending on the types of channel structures of the NAND memory strings (e.g., bottom open channel structure 812 in FIG. 8) and thus, are not elaborated for ease of description.

In some implementations, an interconnect layer is formed above the array of NAND memory strings. The interconnect layer can include a plurality of interconnects in one or more ILD layers. The interconnect layer may include interconnects of MEOL and/or BEOL in a plurality of ILD layers to make electrical connections with the NAND memory strings. In some implementations, the interconnect layer includes multiple ILD layers and interconnects therein formed in multiple processes. For example, the interconnects in the interconnect layer may include conductive materials deposited by one or more thin film deposition processes including, but not limited to, CVD, PVD, ALD, electroplating, electroless plating, or any combination thereof. Fabrication processes to form interconnects can also include photolithography, CMP, wet/dry etch, or any other suitable processes. The ILD layers can include dielectric materials deposited by one or more thin film deposition processes including, but not limited to, CVD, PVD, ALD, or any combination thereof.

As shown in FIG. 19, pad-out interconnect layer 904 may be formed during or after the formation of memory cell array 106. In some implementations, pad-out interconnect layer 904 may be located nearby memory cell array 106 and the contact pad may be above memory cell array 106. Pad-out interconnect layer 904 may be the pad-out of 3D memory devices from memory cell array side in the following operations. Pad-out interconnect layer 904 may include interconnects, such as contact pads, formed in one or more ILD layers. The contact pads may include conductive materials including, but not limited to, W, Co, Cu, Al, doped silicon, silicides, or any combination thereof.

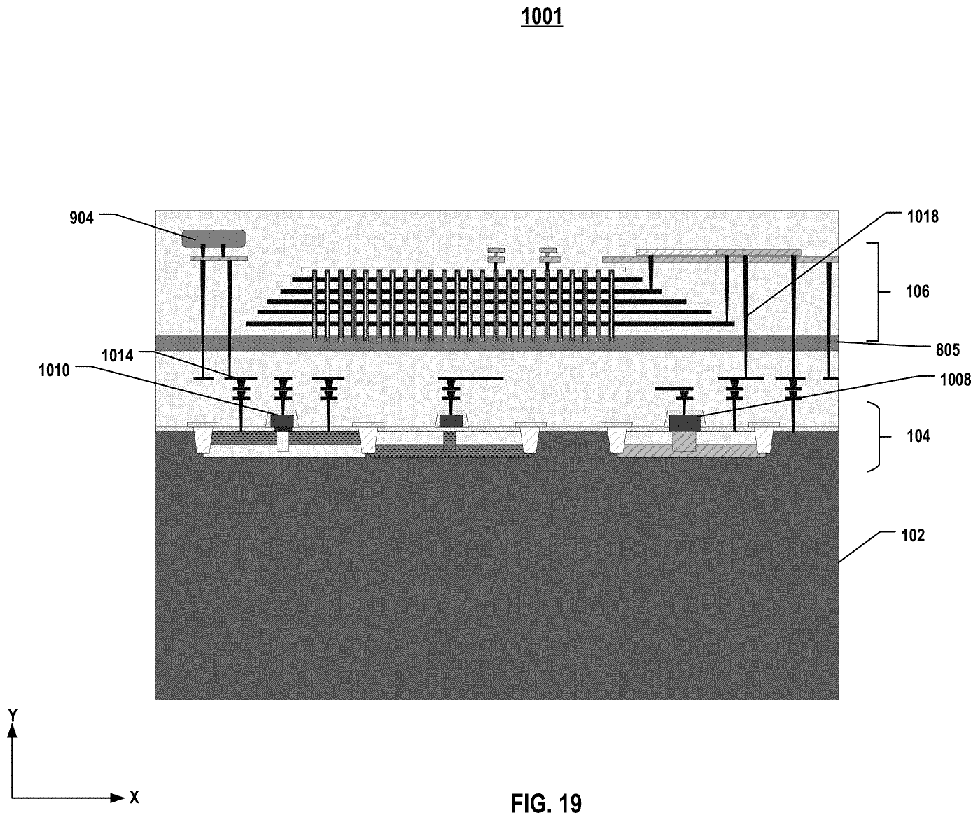

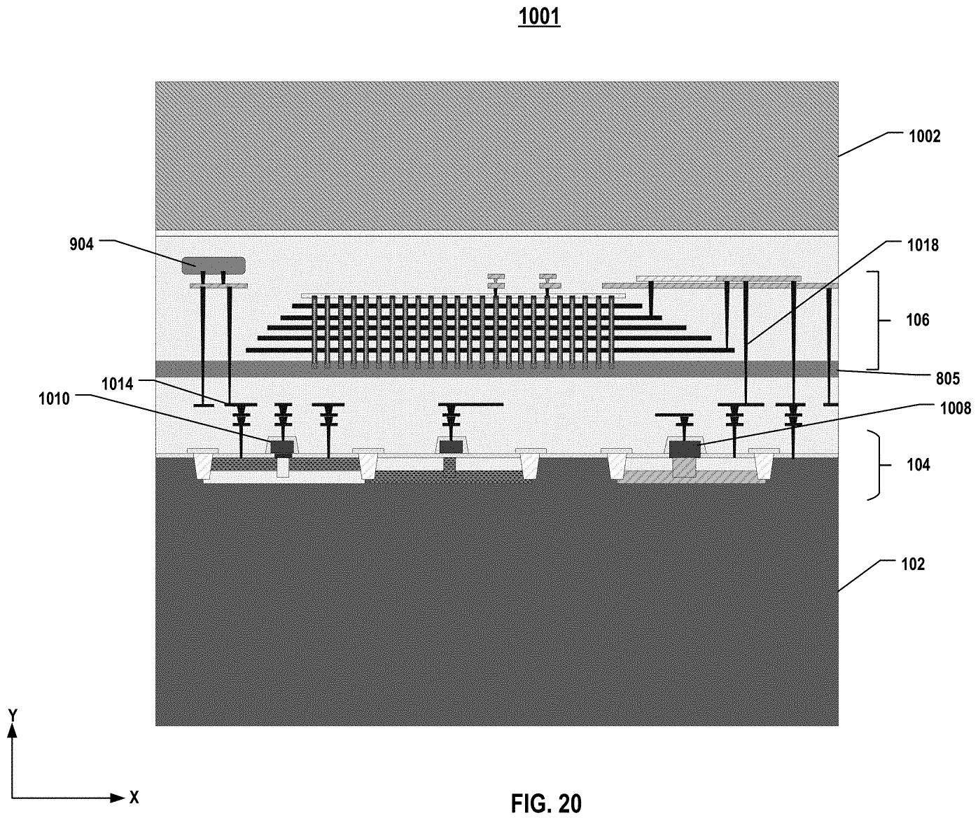

As shown in FIG. 20, after forming memory cell array 106, carrier substrate 1002 may be boned on memory cell array 106. In the following operations, when 3D memory device 1001 is flipped over to perform the fabrication processes of peripheral circuit 108, carrier substrate 1002 may provide the support of 3D memory device 1001. Then, as shown in FIG. 21, 3D memory device 1001 is flipped over. In some implementations, a thinning process may be performed on a second side of substrate 102 to thin substrate 102 to a required thickness. The second side is opposite to the first side of substrate 102 on which peripheral circuit 104 is formed. In some implementations, substrate 102 may be thinned by processes including, but not limited to, wafer grinding, dry etch, wet etch, CMP, any other suitable processes, or any combination thereof.

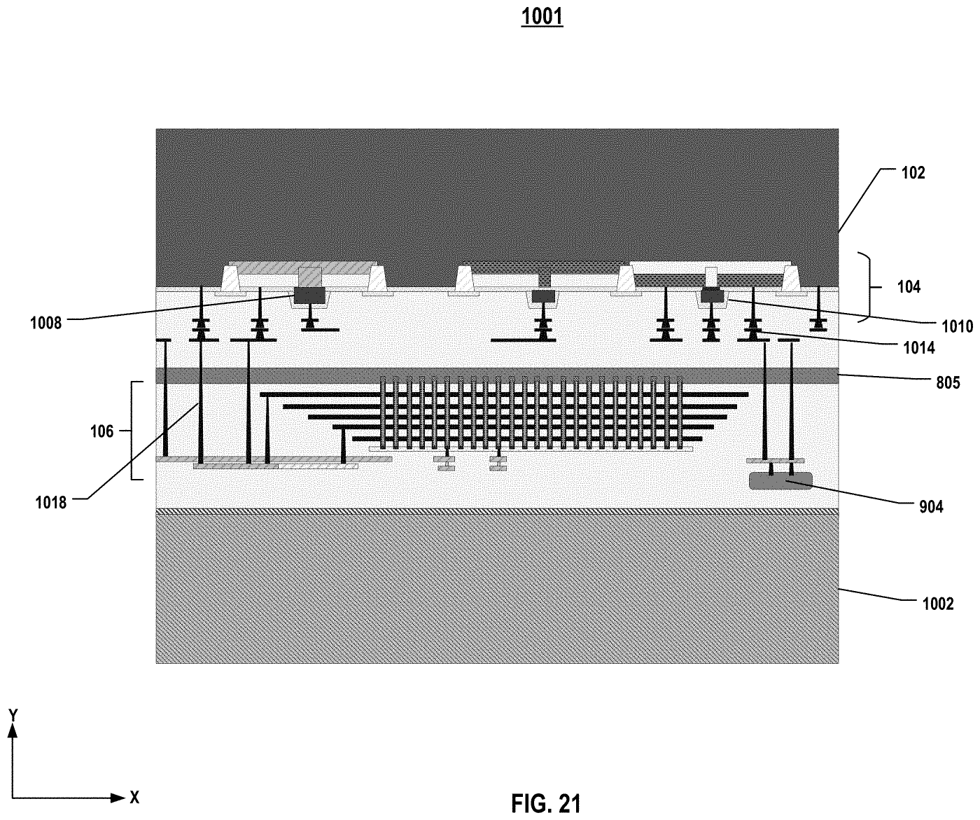

As shown in FIG. 22, peripheral circuit 108 is formed on the second side of substrate 102 opposite to the first side. In some implementations, a plurality of transistors are formed on the second side of substrate 102. The transistors (device circuit 1004 and device circuit 1006) are formed on the second side of substrate 102. The transistors can be formed by a plurality of processes including, but not limited to, photolithography, dry/wet etch, thin film deposition, thermal growth, implantation, CMP, and any other suitable processes. In some implementations, doped regions are formed on the second side of substrate 102 by ion implantation and/or thermal diffusion, which function, for example, as wells and source/drain regions of the transistors. In some implementations, isolation regions (e.g., STIs) are also formed on the second side of substrate 102 by wet/dry etch and thin film deposition. In some implementations, the thickness of gate dielectric of the transistors of device circuit 1004 may be different from the thickness of gate dielectric of the transistors of device circuit 1006, for example, by depositing a thicker silicon oxide film in the region of device circuit 1004 than the region of device circuit 1006, or by etching back part of the silicon oxide film deposited in the region of device circuit 1006. It is understood that the details of fabricating the transistors may vary depending on the types of the transistors (e.g., planar transistors 500 or 3D transistors 600 in FIGS. 5A, 5B, 6A, and 6B) and thus, are not elaborated for ease of description.

In some implementations, interconnect layer 1012 is formed above the transistors. Interconnect layer 1012 may include a plurality of interconnects in one or more ILD layers. Interconnect layer 1012 may include interconnects of MEOL and/or BEOL in a plurality of ILD layers to make electrical connections with device circuit 1004 and device circuit 1006. In some implementations, interconnect layer 1012 includes multiple ILD layers and interconnects therein formed in multiple processes. For example, the interconnects in interconnect layer 1012 may include conductive materials deposited by one or more thin film deposition processes including, but not limited to, CVD, PVD, ALD, electroplating, electroless plating, or any combination thereof. Fabrication processes to form interconnects can also include photolithography, CMP, wet/dry etch, or any other suitable processes. The ILD layers can include dielectric materials deposited by one or more thin film deposition processes including, but not limited to, CVD, PVD, ALD, or any combination thereof.

Different from interconnect layer 1014, in some implementations, the interconnects in interconnect layer 1012 include Cu, which has a relatively low resistivity among conductive metal materials. It is understood that although Cu has a relatively low thermal budget (incompatible with high-temperature processes), using Cu as the conductive materials of the interconnects in interconnect layer 1012 may become feasible since there are no more high-temperature processes after the fabrication of interconnect layer 1012.

In some implementations, a contact through the thinned substrate is formed. As illustrated in FIG. 22, one or more contacts 1016 each extending vertically through substrate 102 are formed. Contacts 1016 may couple the interconnects in interconnect layer 1012 and the interconnects in interconnect layer 1014. Contact 1016 may be formed by first patterning contact holes through substrate 102 using patterning process (e.g., photolithography and dry/wet etch of dielectric materials in the dielectric layer). The contact holes can be filled with a conductor (e.g., W or Cu). In some implementations, filling the contact holes includes depositing a spacer (e.g., a silicon oxide layer) before depositing the conductor.

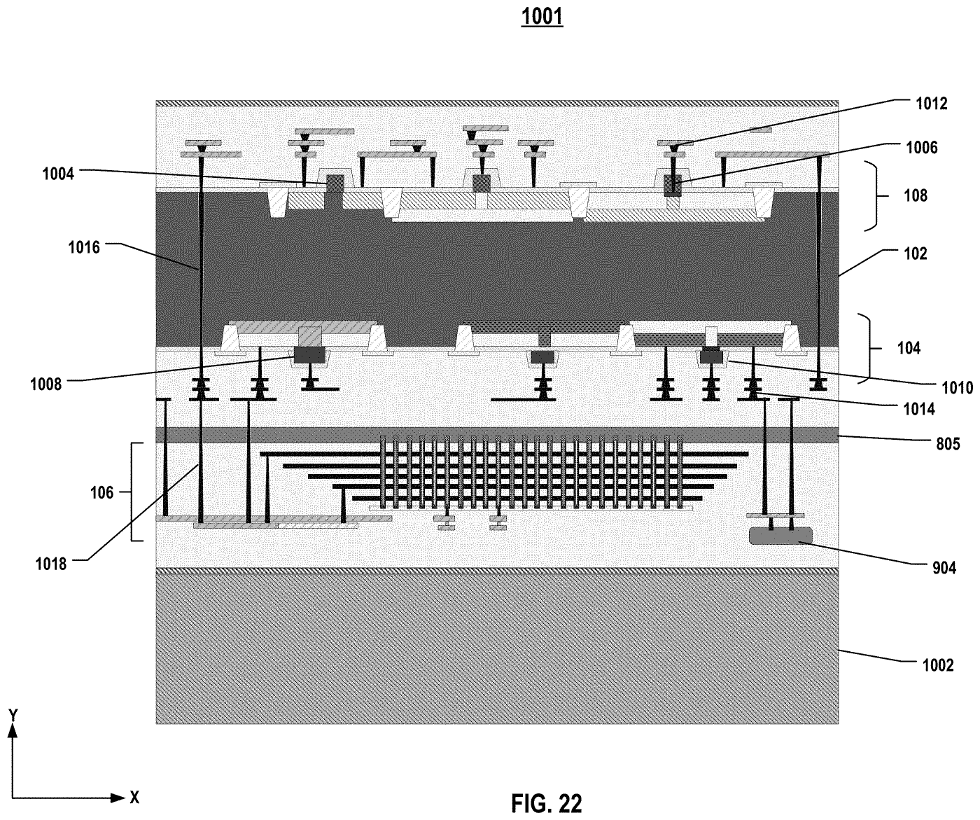

As shown in FIG. 23, 3D memory device 1001 is flipped over, and carrier substrate 1002 is removed. Pad-out interconnect layer 904 is then exposed for external connection.

By forming 3D memory device 1001 with the above operations, a first layer of memory peripheral circuits may be formed on the first side of the substrate, and the memory cell array may be formed on the memory peripheral circuits on the same side of the substrate. Then the substrate may be flipped over and thinned, and a second layer of memory peripheral circuits may be formed on the second side of the substrate opposite to the first side. As a result, the fabrication size of the memory peripheral circuits may be doubled on one substrate to reduce the chip size and the manufacturing cost. Further, the second layer of memory peripheral circuits may be the low-voltage memory peripheral circuits provided with a relatively low voltage (e.g., below 1.3 V), and may be formed after the fabrication of the memory cell array. Hence, the low-voltage memory peripheral circuits will not be affected by the high temperature during the manufacturing of the memory cell array. In addition, the channel length of the low-voltage memory peripheral circuits can be reduced, and the input/output (I/O) speed of the memory devices can be improved as well. In some implementations, the minimality of the channel length of the low-voltage memory peripheral circuits can be further achieved.

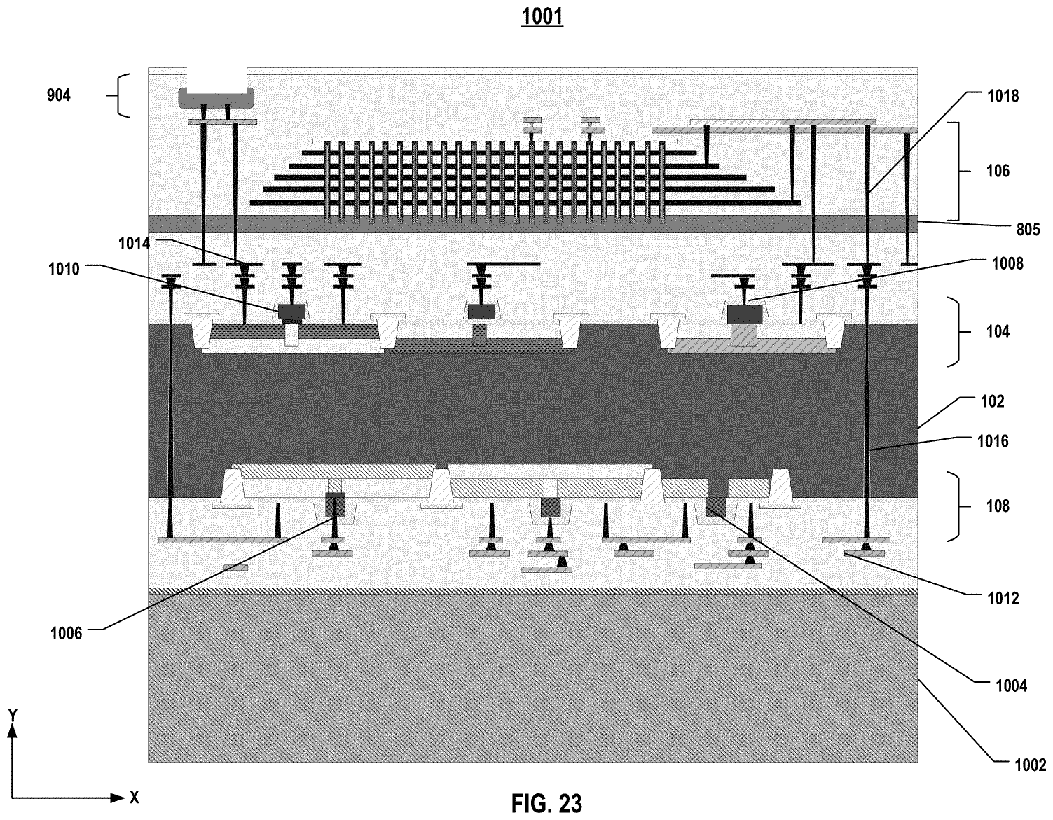

FIG. 24 illustrates a block diagram of a system 1800 having a memory device, according to some aspects of the present disclosure. System 1800 can be a mobile phone, a desktop computer, a laptop computer, a tablet, a vehicle computer, a gaming console, a printer, a positioning device, a wearable electronic device, a smart sensor, a virtual reality (VR) device, an argument reality (AR) device, or any other suitable electronic devices having storage therein. As shown in FIG. 24, system 1800 can include a host 1808 and a memory system 1802 having one or more memory devices 1804 and a memory controller 1806. Host 1808 can be a processor of an electronic device, such as a central processing unit (CPU), or a system-on-chip (SoC), such as an application processor (AP). Host 1808 can be configured to send or receive the data to or from memory devices 1804.

Memory device 1804 can be any memory devices disclosed herein, such as 3D memory devices 100, 200, 900, 901, 1000, and 1001. In some implementations, each memory device 1804 includes an array of memory cells, a first peripheral circuit of the array of memory cells, and a second peripheral circuit of the array of memory cells, which are stacked over one another in different planes, as described above in detail.

Memory controller 1806 is coupled to memory device 1804 and host 1808 and is configured to control memory device 1804, according to some implementations. Memory controller 1806 can manage the data stored in memory device 1804 and communicate with host 1808. In some implementations, memory controller 1806 is designed for operating in a low duty-cycle environment like secure digital (SD) cards, compact Flash (CF) cards, universal serial bus (USB) Flash drives, or other media for use in electronic devices, such as personal computers, digital cameras, mobile phones, etc. In some implementations, memory controller 1806 is designed for operating in a high duty-cycle environment SSDs or embedded multi-media-cards (eMMCs) used as data storage for mobile devices, such as smartphones, tablets, laptop computers, etc., and enterprise storage arrays. Memory controller 1806 can be configured to control operations of memory device 1804, such as read, erase, and program operations. In some implementations, memory controller 1806 is configured to control the array of memory cells through the first peripheral circuit and the second peripheral circuit. Memory controller 1806 can also be configured to manage various functions with respect to the data stored or to be stored in memory device 1804 including, but not limited to bad-block management, garbage collection, logical-to-physical address conversion, wear leveling, etc. In some implementations, memory controller 1806 is further configured to process error correction codes (ECCs) with respect to the data read from or written to memory device 1804. Any other suitable functions may be performed by memory controller 1806 as well, for example, formatting memory device 1804. Memory controller 1806 can communicate with an external device (e.g., host 1808) according to a particular communication protocol. For example, memory controller 1806 may communicate with the external device through at least one of various interface protocols, such as a USB protocol, an MMC protocol, a peripheral component interconnection (PCI) protocol, a PCI-express (PCI-E) protocol, an advanced technology attachment (ATA) protocol, a serial-ATA protocol, a parallel-ATA protocol, a small computer small interface (SCSI) protocol, an enhanced small disk interface (ESDI) protocol, an integrated drive electronics (IDE) protocol, a Firewire protocol, etc.

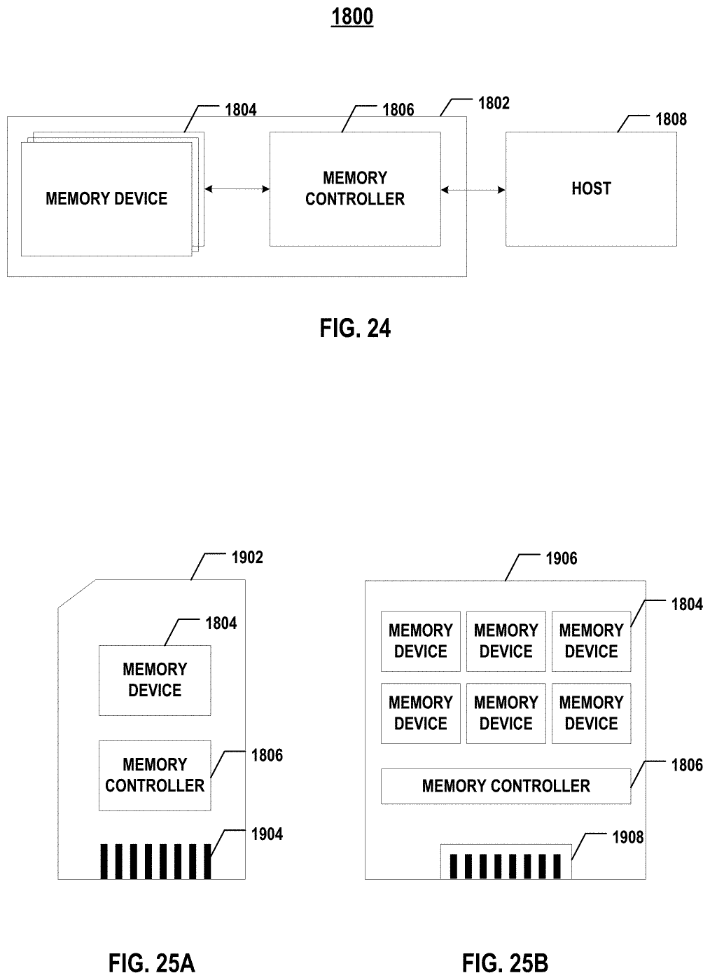

Memory controller 1806 and one or more memory devices 1804 can be integrated into various types of storage devices, for example, be included in the same package, such as a universal Flash storage (UFS) package or an eMMC package. That is, memory system 1802 can be implemented and packaged into different types of end electronic products. In one example as shown in FIG. 25A, memory controller 1806 and a single memory device 1804 may be integrated into a memory card 1902. Memory card 1902 can include a PC card (PCMCIA, personal computer memory card international association), a CF card, a smart media (SM) card, a memory stick, a multimedia card (MMC, RS-MMC, MMCmicro), an SD card (SD, miniSD, microSD, SDHC), a UFS, etc. Memory card 1902 can further include a memory card connector 1904 coupling memory card 1902 with a host (e.g., host 1808 in FIG. 24). In another example as shown in FIG. 25B, memory controller 1806 and multiple memory devices 1804 may be integrated into an SSD 1906. SSD 1906 can further include an SSD connector 1908 coupling SSD 1906 with a host (e.g., host 1808 in FIG. 24). In some implementations, the storage capacity and/or the operation speed of SSD 1906 is greater than those of memory card 1902.

The foregoing description of the specific implementations can be readily modified and/or adapted for various applications. Therefore, such adaptations and modifications are intended to be within the meaning and range of equivalents of the disclosed implementations, based on the teaching and guidance presented herein.

The breadth and scope of the present disclosure should not be limited by any of the above-described exemplary implementations, but should be defined only in accordance with the following claims and their equivalents.

What is claimed is:

1. A three-dimensional (3D) memory device, comprising:
a first semiconductor structure comprising:
a first semiconductor layer; and
an array of NAND memory strings, sources of the array of NAND memory strings being in contact with a first side of the first semiconductor layer; and
a second semiconductor structure under a second side of the first semiconductor layer, the second side of the first semiconductor layer being opposite to the first side of the first semiconductor layer, the second semiconductor structure comprising:
a second semiconductor layer;
a first peripheral circuit of the array of NAND memory strings, the first peripheral circuit comprising a first transistor in contact with a first side of the second semiconductor layer; and
a second peripheral circuit of the array of NAND memory strings, the second peripheral circuit comprising a second transistor in contact with a second side of the second semiconductor layer, the second side of the second semiconductor layer being opposite to the first side of the second semiconductor layer.

2. The 3D memory device of claim 1, wherein the first semiconductor layer is between the array of NAND memory strings and the first peripheral circuit of the array of NAND memory strings.

3. The 3D memory device of claim 1, wherein the first semiconductor layer comprises a polysilicon layer.

4. The 3D memory device of claim 1, wherein the second semiconductor layer comprises a silicon substrate.

5. The 3D memory device of claim 1, wherein the second semiconductor structure further comprises a first interconnect layer and a second interconnect layer such that the first peripheral circuit is between the first interconnect layer and the first side of the second semiconductor layer, and the second peripheral circuit is between the second interconnect layer and the second side of the second semiconductor layer.

6. The 3D memory device of claim 5, wherein the second semiconductor structure further comprises a first through substrate via electrically connected between the first interconnect layer and the second interconnect layer.

7. The 3D memory device of claim 6, wherein the first semiconductor structure further comprises a first contact structure electrically connected between the first interconnect layer and a plurality of word lines of the array of NAND memory strings.

8. The 3D memory device of claim 7, wherein the first contact structure penetrates the first semiconductor layer.

9. The 3D memory device of claim 5, wherein the second semiconductor structure further comprises a pad-out structure, the second peripheral circuit of the array of NAND memory strings is between the pad-out structure and the second side of the second semiconductor structure.

10. The 3D memory device of claim 5, wherein the first semiconductor structure further comprises a pad-out structure, the array of NAND memory strings is between the pad-out structure and the first side of the first semiconductor layer.

11. The 3D memory device of claim 1, wherein
the first transistor comprises a first gate dielectric;
the second transistor comprises a second gate dielectric; and
a thickness of the first gate dielectric is greater than a thickness of the second gate dielectric.

12. A system, comprising:
a memory device configured to store data, and comprising:
a first semiconductor structure comprising:
a first semiconductor layer; and
an array of NAND memory strings, sources of the array of NAND memory strings being in contact with a first side of the first semiconductor layer; and
a second semiconductor structure under a second side of the first semiconductor layer, the second side of the first semiconductor layer being opposite to the first side of the first semiconductor layer, the second semiconductor structure comprising:
a second semiconductor layer;
a first peripheral circuit of the array of NAND memory strings, the first peripheral circuit comprising a first transistor in contact with a first side of the second semiconductor layer; and
a second peripheral circuit of the array of NAND memory strings, the second peripheral circuit comprising a second transistor in contact with a second side of the second semiconductor layer, the second side of the second semiconductor layer being opposite to the first side of the second semiconductor layer; and
a memory controller coupled to the memory device and configured to control the array of NAND memory strings through the first peripheral circuit and the second peripheral circuit.

13. A method for forming a three-dimensional (3D) memory device, comprising:
forming a first transistor on a first side of a substrate;
forming a semiconductor layer over the first transistor on the first side of the substrate;
forming an array of NAND memory strings over the semiconductor layer; and
forming a second transistor on a second side of the substrate opposite to the first side.

14. The method of claim 13, further comprising:
forming a first interconnect layer on the first transistor.

15. The method of claim 14, wherein forming the semiconductor layer over the first transistor on the first side of the substrate, comprises:
forming a polysilicon layer over the first interconnect layer.

16. The method of claim 15, further comprising:
thinning the substrate before forming the second transistor.

17. The method of claim 16, further comprising:
forming a pad-out structure above the array of NAND memory strings on the first side of the substrate.

18. The method of claim 17, further comprising:
forming a first contact structure before forming the pad-out structure, and the first contact structure electrically connected between the first interconnect layer and the pad-out structure.

19. The method of claim 16, further comprising:
forming a pad-out structure above the second transistor on the second side of the substrate.

20. The method of claim 16, further comprising:
forming a through substrate via extending through the substrate.
